(19) United States
(12) Patent Application Publication
(10) Pub. No.: US 2025/0362411 A1
(43) Pub. Date: Nov. 27, 2025

(54) ILLUMINATION DEVICE, DISTANCE MEASURING DEVICE, AND IN-VEHICLE DEVICE

(71) Applicants: SONY SEMICONDUCTOR SOLUTIONS CORPORATION, KANAGAWA (JP); SONY GROUP CORPORATION, Tokyo (JP)

(72) Inventors: TAKASHI KOBAYASHI, KANAGAWA (JP); MIDORI KANAYA, KANAGAWA (JP); MASANAO KAMATA, KANAGAWA (JP); GEN YONEZAWA, KANAGAWA (JP)

(21) Appl. No.: 18/875,136

(22) PCT Filed: Jun. 6, 2023
(86) PCT No.: PCT/JP2023/020952

§ 371 Date: Dec. 14, 2024

(30) Foreign Application Priority Data
Jun. 24, 2022 (JP) 2022-101493

(51) Int. Cl. G01S 17/89; G01S 7/481; G01S 17/931

(52) U.S. Cl. CPC G01S 17/89; G01S 7/4815; G01S 17/931

(57) ABSTRACT

For example, an illumination device is downsized.

An illumination device includes: a plurality of light emitting sections arranged in an array and emitting light beams substantially parallel to each other; a condensing section that condenses a light beam emitted from each light emitting section; and a conversion section that makes light beams diverging after light is condensed substantially parallel to each other and changes emission directions of the light beams.

### TECHNICAL FIELD

The present disclosure relates to an illumination device, a distance measuring device, and an in-vehicle device.

### BACKGROUND ART

An illumination device that irradiates a target object with a light beam is used for applications such as measurement of a spatial propagation time (ToF: Time of Flight) of light, measurement of a distance by structured light, and shape recognition of an object. As such an illumination device, Patent Document 1 below discloses an illumination device in which a surface emitting semiconductor laser (VCSEL: Vertical Cavity Surface Emitting Laser) is used as a light source, and a light beam emitted from the VCSEL is converged by a lens array to form a virtual light emission point (hereinafter, it is appropriately referred to as a virtual light emission point).

### CITATION LIST

### Patent Document

Patent Document 1: US Patent Application Publication No. 2018/329065 A

### SUMMARY OF THE INVENTION

### Problems to be Solved by the Invention

In this field, it is desired to miniaturize the illumination device as much as possible in order to apply the illumination device to many fields.

An object of the present disclosure is to provide an illumination device that can be further downsized, and a distance measuring device and an in-vehicle device including the illumination device.

### Solutions to Problems

The present disclosure provides, for example, an illumination device including:
a plurality of light emitting sections arranged in an array and emitting light beams substantially parallel to each other;
a condensing section that condenses a light beam emitted from each light emitting section; and
a conversion section that makes light beams diverging after light is condensed substantially parallel to each other and changes emission directions of the light beams.

Furthermore, the present disclosure provides, for example,
a distance measuring device including:
the illumination device described above;
a control section that controls the illumination device;
a light receiving section that receives reflected light reflected by a target object; and
a distance measuring section that calculates a distance measurement distance from image data obtained by the light receiving section.

The present disclosure may be an in-vehicle device including the above-described distance measuring device.

### BRIEF DESCRIPTION OF DRAWINGS

FIG. 1 is a block diagram illustrating an example of a schematic configuration of a distance measuring device including an illumination device according to one embodiment.

FIG. 2 is a diagram for explaining a configuration example of the illumination device according to one embodiment.

FIG. 3 is a diagram schematically illustrating a light beam emitted from a light emitting section according to one embodiment.

FIG. 4 is a diagram for explaining a microlens array according to one embodiment.

FIG. 5 is a diagram for explaining the microlens array according to one embodiment.

FIG. 6 is a diagram for explaining the microlens array according to one embodiment.

FIG. 7 is a diagram for explaining a specific numerical example regarding each element of the illumination device according to one embodiment.

A and B of FIG. 8 are diagrams for explaining a first configuration example of the light emitting section according to one embodiment.

FIG. 9 is a diagram for explaining a second configuration example of the light emitting section according to one embodiment.

FIG. 10 is a diagram for explaining a modification of the second configuration example of the light emitting section according to one embodiment.

FIG. 11 is a diagram for explaining a third configuration example of the light emitting section according to one embodiment.

FIG. 12 is a diagram for explaining an example of a linear light beam according to one embodiment.

FIG. 13 is a diagram for explaining a diffusion plate according to one embodiment.

FIG. 14 is a diagram for explaining an arrangement example of a diffusion plate according to one embodiment.

A and B of FIG. 15 are diagrams for explaining an example of the action of a cylindrical lens and a diffusion plate according to one embodiment.

FIG. 16 is a diagram for explaining an arrangement example of a cylindrical lens and a diffusion plate according to one embodiment.

FIG. 17 is a diagram for explaining an example of a duplicated linear light beam.

FIG. 18 is a diagram for explaining an arrangement example of a diffraction grating according to one embodiment.

FIG. 19 is a diagram for explaining another example of the duplicated linear light beam.

FIG. 20 is a diagram to be referred to when a configuration including a driving section according to one embodiment is described.

FIG. 21 is a diagram to be referred to when a configuration including a driving section according to one embodiment is described.

FIG. 22 is a diagram for explaining an example of a scanned linear light beam.

FIG. 23 is a diagram for explaining an arrangement mode example of a plurality of light emitting elements according to one embodiment.

FIG. 24 is a diagram illustrating an optical lens diameter and an arrangement mode example of a plurality of light emitting elements according to one embodiment.

FIG. 25 is a diagram for explaining another example of the light emitting element according to one embodiment.

FIG. 26 is a diagram for explaining another example of the light emitting element according to one embodiment.

FIG. 27 is a diagram to be referred to when a driving method of the illumination device according to one embodiment is described.

FIG. 28 is a diagram to be referred to when a driving method of the illumination device according to one embodiment is described.

FIG. 29 is a diagram to be referred to when a driving method of the illumination device according to one embodiment is described.

FIG. 30 is a diagram to be referred to when a driving method of the illumination device according to one embodiment is described.

FIG. 31 is a block diagram depicting an example of schematic configuration of a vehicle control system.

FIG. 32 is a diagram of assistance in explaining an example of installation positions of an outside-vehicle information detecting section and an imaging section.

### MODE FOR CARRYING OUT THE INVENTION

Hereinafter, an embodiment and the like of the present disclosure will be described with reference to the drawings. Note that the description will be given in the following order.

### Problems to be Considered in the Present Disclosure

### One Embodiment

### Modifications

### Application Examples

Note that the embodiment and the like to be described below are preferred specific examples of the present disclosure, and the content of the present disclosure is not limited to this embodiment and the like. Note that, in the following description, components having substantially the same functional configuration are denoted by the same reference signs, and redundant description will be omitted as appropriate. In addition, in order to prevent the illustration from being complicated, only some configurations may be denoted by reference signs, or the illustration may be simplified or enlarged/reduced.

### Problems to Be Considered in the Present Disclosure

First, problems to be considered in the present disclosure will be described in order to facilitate understanding of the present disclosure. In order to condense the light beam from the light emitting section smaller (to a higher light density) at the virtual light emission point, it is desirable that the focal length of the lens array be short. As described in Patent Document 1, in a case where the VCSEL is used as the light emitting section, the light beam from the VCSEL is divergent light exceeding 10 degrees, and when the focal length of the lens array is short, the divergence angle of the light beam from the virtual light emission point further increases. When the divergence angle of the light beam increases, the optical lens for forming the parallel light beam arranged in the traveling direction of the light beam increases in size. In addition, it becomes difficult to suppress the lens aberration with respect to the light beam from the region around the arranged light emitting section, the distance measuring performance around the light emitting section deteriorates, and the lens configuration becomes complicated in order to suppress the lens aberration, and the illumination device becomes expensive. Furthermore, in a case where the light beam from the light emitting section is divergent light having a large divergence angle, it is necessary to further increase the diameter (lens diameter) of each lens array arranged beyond the light emitting section with respect to the area of the light emitting section. When the distance between the light emitting section and the lens array increases, the lens diameter of the lens array further increases. In addition, in order to prevent interference between a light beam emitted from a certain light emitting section and a light beam emitted from a light emitting section adjacent to the light emitting section, it is necessary to increase an interval between the light emitting sections, and as a result, the illumination device becomes large. In addition, the light emitting element including the light emitting section becomes expensive. Based on the above points, one embodiment of the present disclosure will be described in detail.

### One Embodiment

### Configuration Example of Distance Measuring Device

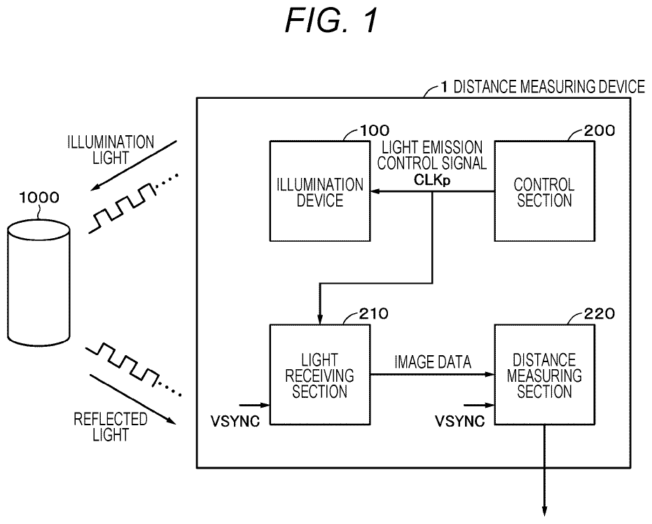

FIG. 1 is a block diagram illustrating a configuration example of a distance measuring device (distance measuring device 1) to which an illumination device (illumination device 100) according to one embodiment can be applied. The distance measuring device 1 is a device that irradiates an irradiation target 1000 with illumination light and receives the reflected light to measure the distance (distance measurement distance) to the irradiation target 1000. The distance measuring device 1 employs, for example, a ToF method or a Structured Light method. The ToF method is a method of calculating the distance from the time until the light beam emitted from the distance measuring device is reflected by the measuring target object and returns to the distance measuring device. The Structured Light method is a method of irradiating the measuring target object with a pattern of a light beam from the distance measuring device and calculating the distance from distortion of the pattern of the light beam reflected and returned to the distance measuring device.

The distance measuring device 1 includes an illumination device 100, a control section 200 that controls the illumination device 100, a light receiving section 210, and a distance measuring section 220. The illumination device 100 generates irradiation light in synchronization with a light emission control signal CLKp of a rectangular wave from the control section 200. The light emission control signal CLKp is only required to be a periodic signal, and is not limited to the rectangular wave. For example, the light emission control signal CLKp may be a sine wave.

The light receiving section 210 receives the reflected light reflected from the irradiation target 1000 and detects, each time a cycle of a vertical synchronization signal VSYNC elapses, an amount of received light within the cycle. In the light receiving section 210, a plurality of pixel circuits is arranged in a two-dimensional lattice pattern, for example. The light receiving section 210 supplies image data (frame) corresponding to an amount of light received by these pixel circuits to the distance measuring section 220. Note that the light receiving section 210 may have a function of correcting a distance measurement error due to multipath.

The control section 200 controls the illumination device 100 and the light receiving section 210. The control section 200 generates the light emission control signal CLKp and supplies the same to the illumination device 100 and the light receiving section 210.

The distance measuring section 220 measures a distance to the irradiation target 1000 by a ToF method or the like on the basis of the image data. The distance measuring section 220 measures the distance for each pixel circuit and generates a depth map indicating a distance to an object as a grayscale value for each pixel. This depth map is used for, for example, image processing of performing blurring processing to a degree according to a distance, autofocus (AF) processing of obtaining a focus of a focus lens according to a distance, distance measurement to a target object in in-vehicle LiDAR, and the like.

### Illumination Device

### Configuration Example

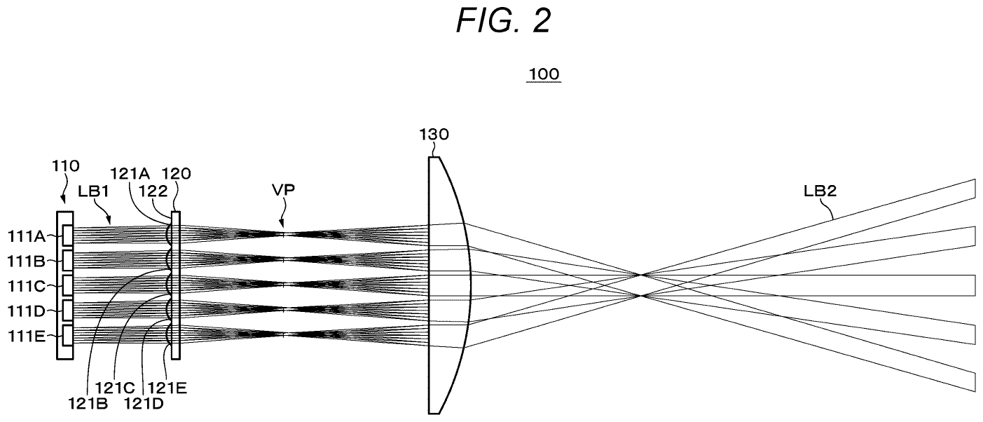

FIG. 2 is a diagram for explaining a configuration example of the illumination device 100. The illumination device 100 includes, for example, a light emitting element 110, a microlens array 120, and an optical lens 130.

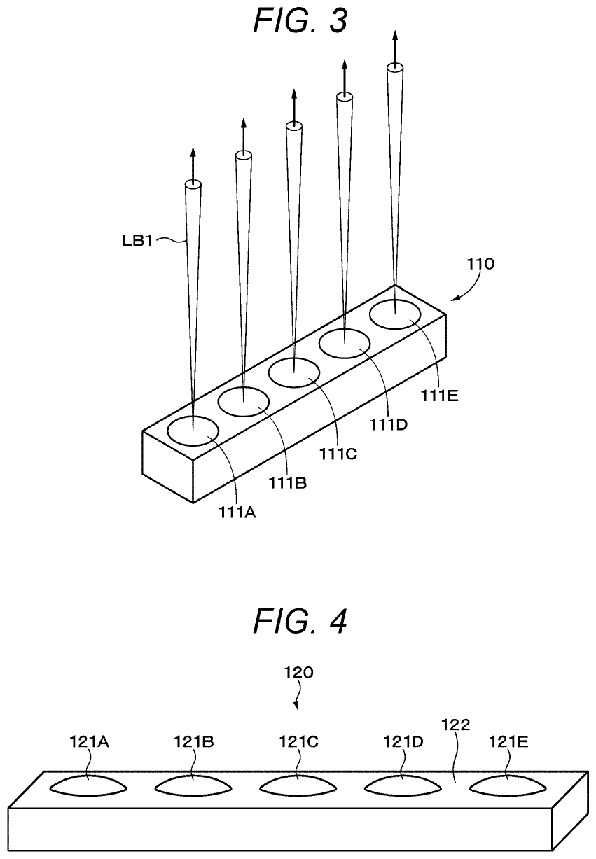

The light emitting element 110 is a light source of the illumination device 100, and includes a plurality of light emitting sections. FIG. 2 illustrates an example in which the light emitting elements 110 have five light emitting sections 111A, 111B, 111C, 111D, and 111E arranged in an array (in the present example, a line shape is formed). Of course, the number of light emitting sections is not limited to five, and may be an appropriate number. In addition, the plurality of light emitting sections may be arranged not one-dimensionally but two-dimensionally or three-dimensionally. Note that, in the following description, in a case where it is not necessary to distinguish the individual light emitting sections, the light emitting sections are appropriately collectively referred to as light emitting section 111. As schematically illustrated in FIG. 3, each of the plurality of light emitting sections 111 emits a light beam LB1 having a small divergence angle, that is, a substantially parallel light beam LB1. Note that a specific configuration example of the light emitting section 111 will be described later.

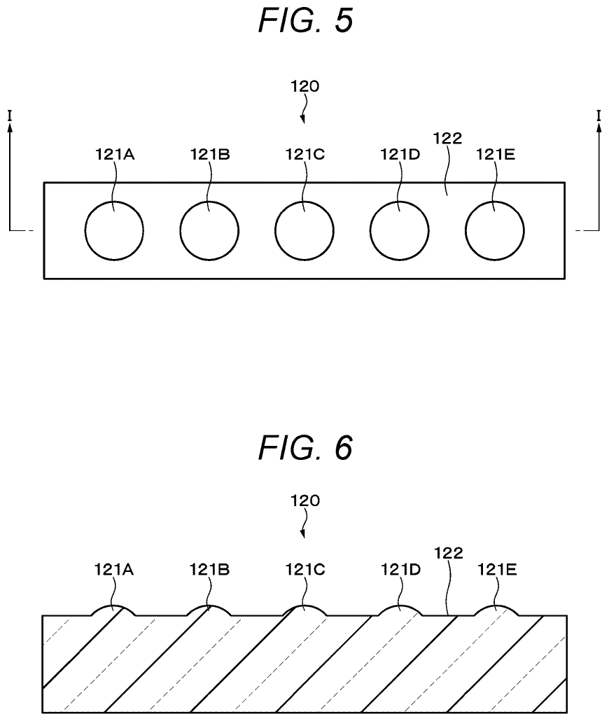

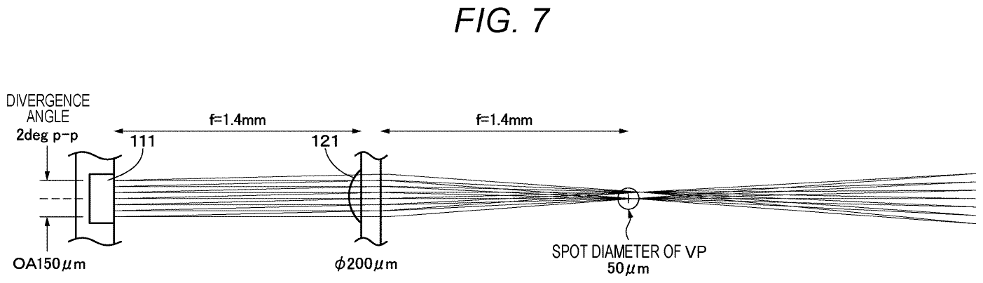

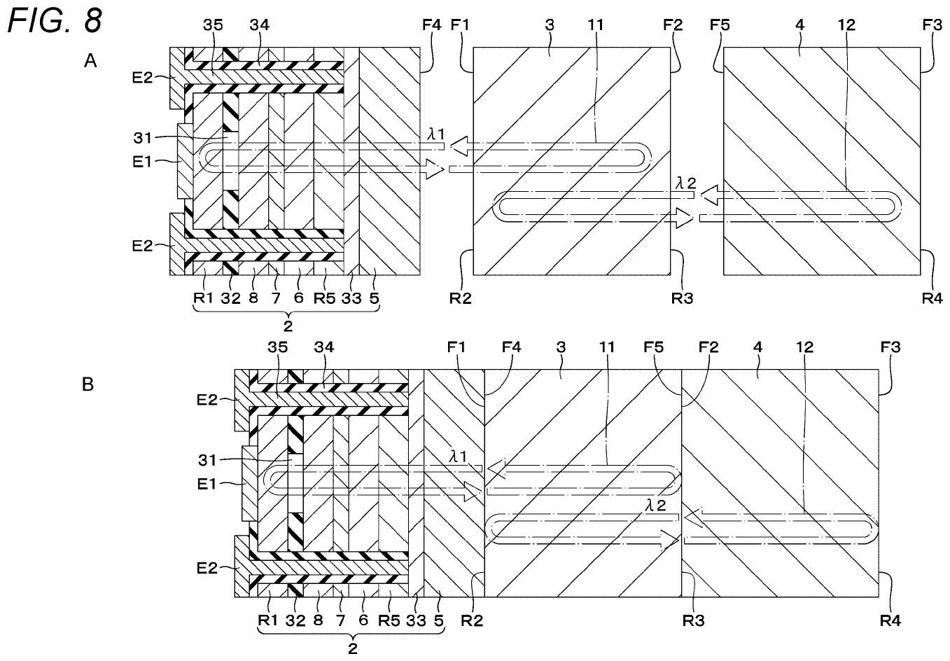

The microlens array 120, which is an example of the condensing section, condenses light beams LB emitted from light emitting sections 111. An example of the microlens array 120 will be described with reference to FIGS. 4 to 6. FIGS. 4 to 6 are a perspective view of the microlens array 120, a diagram illustrating a planar configuration example of the microlens array 120, and a diagram illustrating a cross-sectional configuration of the microlens array 120 taken along line I-I illustrated in FIG. 5, respectively.

The microlens array 120 includes a plurality of lens sections and a parallel plate section 122. In the present example, the microlens array 120 includes five lens sections (lens section 121A, lens section 121B, lens section 121C, lens section 121D, and lens section 121E). Note that, in the following description, in a case where it is not necessary to distinguish the individual lens sections, the individual lens sections are appropriately collectively referred to as lens section 121. The lens section 121 is disposed so as to face the light emitting section 111. For example, as illustrated in FIG. 2, the lens section 121A is disposed so as to face the light emitting section 111A. The lens section 121B is disposed so as to face the light emitting section 111B. The lens section 121C is disposed so as to face the light emitting section 111C. The lens section 121D is disposed so as to face the light emitting section 111D. The lens section 121E is disposed so as to face the light emitting section 111E.

The light beam LB1 emitted from the light emitting section 111 is refracted by the lens surface of the lens section 121 and condensed to form a virtual light emission point VP (see FIG. 2). Note that the virtual light emission point VP may be formed not between the microlens array 120 and the optical lens 130 but in the microlens array 120.

The optical lens 130, which is an example of the conversion section, makes the light beams diverging after the light is condensed at the virtual light emission point VP by the microlens array 120 substantially parallel, and changes the emission directions of the respective light beams. The irradiation target 1000 is irradiated with the light beam LB2 emitted through the optical lens 130, and reflected light from the irradiation target 1000 is received by the light receiving section 210. Note that a Fresnel lens or metamaterial may be used instead of the optical lens 130. In addition, the light beam LB2 may be scanned using a one-dimensional mechanical scanning mechanism such as a galvanometer mirror or a micro electro mechanical systems (MEMS) mirror.

### Specific Examples of Numerical Values

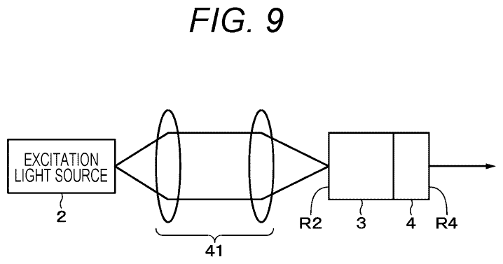

Next, specific examples of numerical values of the respective elements constituting the illumination device 100 will be described with reference to FIG. 7. The light emitting section 111 has, for example, a light emission area having an OA diameter (diameter) of approximately 150 μm. The divergence angle (p-p (full-width display)) of the light beam emitted from the light emitting section 111 is desirably as small as possible from the viewpoint of reducing the size of the illumination device 100, and is ideally 0 degrees, and can be 2 degrees or less according to the light emitting section 111 according to the present embodiment.

The lens section 121 of the microlens array 120 has a diameter of approximately 200 μm. The lens section 121 is disposed at a distance substantially equal to a focal length (for example, approximately 1.4 mm) of the lens section 121 with respect to the light emitting section 111. The light beam LB1 emitted from the light emitting section 111 by the lens section 121 is condensed on a light spot having a diameter of approximately 50 μm at the virtual light emission point VP. The condensed light spot then enters the optical lens 130 as a light beam of divergent light of approximately 6 degrees. The light beams LB1 from the light emitting section 111 become substantially parallel light beams LB2 (parallel light beams) directed in a predetermined direction by the optical lens 130 (see FIG. 2), and are applied to the irradiation target 1000.

### Specific Example of Light Emitting Section

### First Configuration Example

Next, a specific configuration example of the light emitting section 111 will be described. First, a first configuration example will be described. FIG. 8 is a diagram illustrating a configuration example of the light emitting section 111 according to the present example. As illustrated in FIG. 8A, the light emitting section 111 according to the present example includes an excitation light source 2 which is an example of an excitation light source layer, a solid-state laser medium 3 which is an example of a laser medium, and a saturable absorber 4, and has a structure in which the excitation light source 2, the solid-state laser medium 3, and the saturable absorber 4 are integrally joined and laminated as illustrated in FIG. 8B. The optical axes of the excitation light source 2, the solid-state laser medium 3, and the saturable absorber 4 are arranged on one axis, for example.

The excitation light source 2 is a partial structure of the VCSEL and has a laminated semiconductor layer having a laminated structure. The excitation light source 2 in FIG. 8 has a structure obtained by laminating a substrate 5, an n-contact layer 33, a fifth reflection layer R5, a cladding layer 6, an active layer 7, a cladding layer 8, a pre-oxidation layer 31, and a first reflection layer R1 in this order. Note that, in the example illustrated in FIG. 8, a bottom emission type configuration in which continuous wave (CW) excitation light is emitted from the substrate 5 is illustrated, but the light emitting section 111 may have a top emission type configuration in which CW excitation light is emitted from the first reflection layer R1 side.

The substrate 5 is, for example, an n-GaAs substrate 5. The n-GaAs substrate 5 absorbs light of a first wavelength λ1, which is the excitation wavelength of the excitation light source 2, at a certain rate, and hence is desirable to make the n-GaAs substrate 5 as thin as possible. In contrast, it is desirable to provide such a thickness that can maintain mechanical strength at the time of a joining process to be described later.

The active layer 7 performs surface emission at the first wavelength λ1. The cladding layers 6 and 8 are, for example, AlGaAs cladding layers. The first reflection layer R1 reflects the light having the first wavelength λ1. The fifth reflection layer R5 has a certain transmittance with respect to the light having the first wavelength λ1. For the first reflection layer R1 and the fifth reflection layer R5, for example, a semiconductor distributed Bragg reflector (DBR) capable of performing electrical conduction is used. A current is externally injected via the first reflection layer R1 and the fifth reflection layer R5, recombination and light emission occur in a quantum well in the active layer 7, and laser oscillation at the first wavelength λ1 is performed. A part of the pre-oxidation layer (for example, AlAs layer) 31 on the cladding layer side of the first reflection layer R1 is oxidized to become a post-oxidation layer (for example, Al₂O₃ layer) 32.

The fifth reflection layer R5 is arranged on, for example, the n-GaAs substrate 5. For example, the fifth reflection layer R5 includes a multilayer reflection film containing Al_{z1}Ga_{1-z1}As/Al_{z2}Ga_{1-z2}As (0≤z1≤z2≤1) to which an n-type dopant (for example, silicon) is added. The fifth reflection layer R5 is also referred to as an n-DBR. More specifically, the n-contact layer 33 is disposed between the fifth reflection layer R5 and the n-GaAs substrate 5.

The active layer 7 includes, for example, a multiple quantum well layer in which an Alₓ₁In_{y1}Ga_{1-x1-y1}As layer and an Alₓ₃In_{y3}Ga_{1-x3-y3}As layer are laminated.

The first reflection layer R1 includes, for example, a multilayer reflection film containing Al_{z3}Ga_{1-z3}As/Al_{z4}Ga_{1-z4}As (0≤z3≤z4≤1) to which a p-type dopant (for example, carbon) is added. The first reflection layer R1 is also referred to as a p-DBR.

Each semiconductor layer (R5, 6, 7, 8, R1) in the excitation light source 2 can be formed using a metal organic chemical vapor deposition (MOCVD) method or a crystal growth such as a molecular beam epitaxy (MBE) method. Then, after the crystal growth, driving by current injection becomes possible after processes such as mesa etching for element separation, formation of an insulating film, and vapor deposition of an electrode film.

The solid-state laser medium 3 is joined to the end face on the side opposite to the fifth reflection layer R5 of the n-GaAs substrate 5 of the excitation light source 2. Hereinafter, the end face on the excitation light source 2 side of the solid-state laser medium 3 is referred to as a first surface F1, and the end face on the saturable absorber 4 side of the solid-state laser medium 3 is referred to as a second surface F2. Furthermore, a laser pulse emission surface of the saturable absorber 4 is referred to as a third surface F3, and the end face on the solid-state laser medium side of the excitation light source 2 is referred to as a fourth surface F4. Furthermore, the end face on the solid-state laser medium 3 side of the saturable absorber 4 is referred to as a fifth surface F5. As illustrated in FIG. 8B, the fourth surface F4 of the excitation light source 2 is joined to the first surface F1 of the solid-state laser medium 3, and the second surface F2 of the solid-state laser medium 3 is joined to the fifth surface F5 of the saturable absorber 4. The solid-state laser medium 3 is disposed on the rear side of the optical axis of the excitation light source 2. The rear side of the optical axis is an emission direction of light on the optical axis. In addition, the solid-state laser medium 3 has a second reflection layer R2 for a second wavelength λ2 on the first surface F1 facing the excitation light source 2 and a third reflection layer R3 for the first wavelength λ1 on the second surface F2 opposite to the first surface F1.

The light emitting section 111 according to the present example includes a first resonator 11 and a second resonator 12. The first resonator 11 causes the light of the first wavelength λ1 to resonate between the first reflection layer R1 in the excitation light source 2 and the third reflection layer R3 in the solid-state laser medium 3. The second resonator 12 causes the light of the second wavelength λ2 to resonate between the second reflection layer R2 in the solid-state laser medium 3 and the fourth reflection layer R4 in the saturable absorber 4.

The second resonator 12 is also referred to as a Q-switched solid-state laser resonator. The third reflection layer R3, which is a high reflection layer, is provided in the solid-state laser medium 3 so that the first resonator 11 can perform a stable resonance operation. In the normal excitation light source 2, a partial reflector for emitting the light of the first wavelength λ1 to the outside is disposed at a position of the third reflection layer R3. On the other hand, in the light emitting section 111 according to the present example, the third reflection layer R3 is used as a high reflection layer in order to confine the power of the excitation light having the first wavelength λ1 in the first resonator 11.

In this manner, three reflection layers (first reflection layer R1, fifth reflection layer R5, and third reflection layer R3) are provided inside the first resonator 11 including the excitation light source 2 and the solid-state laser medium 3. Therefore, the first resonator 11 has a coupled resonator (Coupled Cavity) structure.

The solid-state laser medium 3 is excited by confining the power of the excitation light of the first wavelength λ1 in the first resonator 11. Thus, Q-switched laser pulse oscillation occurs in the second resonator 12. The second resonator 12 causes light having the second wavelength λ2, which is an oscillation wavelength, to resonate between the second reflection layer R2 in the solid-state laser medium 3 and the fourth reflection layer R4 in the saturable absorber 4. The second reflection layer R2 is a high reflection layer, whereas the fourth reflection layer R4 is a partial reflection layer. In FIG. 8, the fourth reflection layer R4 is provided on the end face (third surface F3) of the saturable absorber 4, but the fourth reflection layer R4 may be disposed on the rear side of the optical axis with respect to the saturable absorber 4. That is, the fourth reflection layer R4 is not necessarily provided inside or on the surface of the saturable absorber 4. The fourth reflection layer R4 is an output coupling mirror in the second resonator 12.

The solid-state laser medium 3 contains, for example, ytterbium (Yb)-doped yttrium aluminum garnet (YAG) crystal Yb:YAG. In this case, the first wavelength (excitation wavelength) λ1 is 940 nm, and the second wavelength (oscillation wavelength) λ2 is 1030 nm. In addition, in a case where an yttrium aluminum garnet (YAG) crystal Nd:YAG doped with neodymium (Nd) is used, a combination of the first wavelength λ1 of 808 nm and 885 nm and the second wavelength λ2 of 946 nm and 1064 nm can be adopted. Furthermore, in a case where the glass material Er, Yb:glass doped with Er and Yb is used, the first wavelength λ1 is 975 nm and the second wavelength λ2 is 1535 nm.

The relationship between the absorption wavelength and the oscillation wavelength is determined by photon energy emitted when light having photon energy corresponding to an energy difference between energy levels of atoms in the laser medium is absorbed and excited, and the light is guided to transition to a selected lower level. Therefore, the relationship between the absorption wavelength and the oscillation wavelength is not limited to that described herein.

The solid-state laser medium 3 is not limited to Yb:YAG and Nd:YAG, and at least one material of Nd:GdVO₄, Nd:KLu (WO₄)₂, Nd:YVO₄, Nd:YLF, Nd:glass, Yb:YAG, Yb:YLF, Yb:FAP, Yb:SFAP, Yb:YVO, Yb:KYW, Yb:BCBF, Yb:YCOB, Yb:GdCOB, YB:YAB, Er, Yb:YAl₃ (BO₃)₄, Er, Yb:GdAl₃ (BO₃)₄, or Er, Yb:glass can be used. The form is not limited to crystal, and the use of a ceramic material is not prevented.

An example of the relationship among the material of the solid-state laser medium 3, the first wavelength λ1, and the second wavelength λ2 is illustrated in Table 1 below.

| Excitation | Q-switched | |
|---|---|---|
| light source | oscillation | |
| wavelength | wavelength | Material |
| 808 | 912 | Nd:GdVO₄ |
| 880 | 1355 | Nd:KLu(WO₄)₂ |
| 976 | 1522 | Er, Yb:YAl₃(BO₃)₄ |
| 976 | 1550 | Er, Yb:GdAl₃(BO₃)₄ |
| 975 | 1535 | Er, Yb:glass |

Furthermore, the solid-state laser medium 3 may be a four-level system solid-state laser medium 3 or a quasi-three-level system solid-state laser medium 3.

The saturable absorber 4 contains, for example, a chromium (Cr)-doped YAG (Cr:YAG) crystal. The saturable absorber 4 is a material in which the transmittance increases when the intensity of incident light exceeds a predetermined threshold. The excitation light of the first wavelength λ1 by the first resonator increases the transmittance of the saturable absorber 4 to emit the laser pulse of the second wavelength λ2. This is referred to as Q-switching. As the material of the saturable absorber 4, V:YAG can also be used. However, other types of saturable absorber 4 may also be used. A semiconductor saturable absorber mirror (SESAM) having a quantum well may be used. Furthermore, the use of an active Q-switched element as the Q-switching is not prevented.

As illustrated in FIG. 8B, the excitation light source 2, the solid-state laser medium 3, and the saturable absorber 4 have a laminated structure in which the excitation light source 2, the solid-state laser medium 3, and the saturable absorber 4 are joined and integrated using a joining process. Examples of the joining process include surface activation joining, atomic diffusion joining, plasma activation joining, and the like. Alternatively, other joining (bonding) processes can be used.

To stably join the solid-state laser medium 3 to the excitation light source 2, it is necessary to flatten the surface of the n-GaAs substrate 5 in the excitation light source 2. Therefore, as described above, it is desirable that electrodes E1 and E2 for injecting a current into the first reflection layer R1 and the fifth reflection layer R5 be arranged so as not to be exposed at least on the surface of the n-GaAs substrate 5. In the example illustrated in FIGS. 8A and 8B, electrodes E1 and E2 are disposed on the end face of the excitation light source 2 on the first reflection layer R1 side. The electrode E1 is a p-electrode, and is electrically conducted with the first reflection layer R1. The electrode E2 is an n-electrode, and is formed by filling an inner wall of a trench reaching the n-contact layer 33 from the first reflection layer R1 with a conductive material 35 via an insulating film 34. As illustrated in FIGS. 8A and 8B, by arranging the electrodes E1 and E2 on the same end face of the excitation light source 2, this end face can be soldered to a support substrate (not illustrated). Also, when a plurality of light emitting sections 111 is arranged in an array, arranging the electrodes E1 and E2 on the same end face enables this end face to be mounted on the support substrate. Note that the shapes and arrangement positions of the electrodes E1 and E2 illustrated in FIGS. 8A and 8B are merely examples.

In this way, by forming the light emitting section 111 in a laminated structure, it is easy to form a plurality of chips by dicing after fabricating a laminated structure, or to form the light emitting element 110 in which a plurality of light emitting sections 111 is arranged in an array on one substrate.

In a case where the light emitting section 111 having the laminated structure is fabricated by the joining process, arithmetic average roughness Ra of each surface layer needs to be about 1 nm or less, and is desirably 0.5 nm or less. Chemical mechanical polishing (CMP) is used to implement the surface layer having such arithmetic average roughness. Furthermore, in order to avoid an optical loss at an interface of each layer, a dielectric multilayer film may be arranged between the layers, and the layers may be joined via the dielectric multilayer film. For example, the GaAs substrate 5 as the base substrate of the excitation light source 2 has a refractive index n of 3.2 with respect to a wavelength of 940 nm, which is higher than that of YAG (n: 1.7) or a general dielectric multilayer film material. Therefore, when the solid-state laser medium 3 and the saturable absorber 4 are joined to the excitation light source 2, it is necessary to prevent optical loss due to refractive index mismatch from occurring. Specifically, it is desirable to dispose an anti-reflection film (AR coating film or non-reflection coating film) that does not reflect the light of the first wavelength λ1 of the first resonator 11 between the excitation light source 2 and the solid-state laser medium 3. Furthermore, it is desirable to arrange an anti-reflection film (AR coating film or non-reflection coating film) also between the solid-state laser medium 3 and the saturable absorber 4.

Polishing is sometimes difficult depending on a joining material, and for example, a material that is transparent with respect to the first wavelength λ1 and the second wavelength λ2, such as SiO₂, may be deposited as a base layer for joining, and this SiO₂ layer may be polished to have arithmetic average roughness Ra of about 1 nm (preferably 0.5 nm or less) and used as an interface for joining. Here, a material other than SiO₂ can be used as the base layer, and the material is not limited. Note that a non-reflection film may be provided between SiO₂ as the material of the base layer and a base material layer.

Examples of the dielectric multilayer film include a short wave pass filter (SWPF), a long wave pass filter (LWPF), a band pass filter (BPF), an anti-reflection (AR) protective film, and the like, and the dielectric multilayer film is a coating layer formed by alternately laminating a high refractive material layer and a low refractive material layer. It is desirable to arrange different types of dielectric multilayer films as necessary. A physical vapor deposition (PVD) method can be used as a film deposition method of the dielectric multilayer film, and specifically, the film deposition method such as vacuum vapor deposition, ion-assisted vapor deposition, and sputtering can be used. It does not matter which film deposition method is applied. Furthermore, any characteristic of the dielectric multilayer film can be selected, and for example, the second reflection layer R2 may be the short wave pass filter, and the third reflection layer R3 may be the long wave pass filter. Furthermore, applying the long wave pass filter to the third reflection layer R3 makes it possible to prevent the first wavelength λ1 from entering the saturable absorber 4 and to prevent malfunction of the Q-switching. Note that the short wave pass means that the light of the first wavelength λ1 is transmitted and the light of the second wavelength λ2 is reflected. Furthermore, the long wave pass means that the light of the first wavelength λ1 is reflected and the light of the second wavelength λ2 is transmitted.

Furthermore, a polarizer having a photonic crystal structure that separates a ratio of P-polarized light and S-polarized light may be provided inside the second resonator 12. Furthermore, it is possible to provide a diffraction grating inside the second resonator 12 to convert the polarization state of the emitted laser pulse from random polarization to linear polarization. The fine groove portion of the photonic crystal structure or the diffraction grating can be used as an interface for joining by depositing a film of a material such as SiO₂ and polishing the film.

Next, the operation of the light emitting section 111 according to the present example will be described. By injecting a current into the active layer 7 via the electrode of the excitation light source 2, laser oscillation at the first wavelength λ1 occurs in the first resonator 11, and the solid-state laser medium 3 is excited. Since the saturable absorber 4 is joined to the solid-state laser medium 3, in an initial stage when the laser oscillation at the first wavelength λ1 occurs, the spontaneous emission light from the solid-state laser medium 3 is absorbed by the saturable absorber 4, so that optical feedback by the fourth reflection layer R4 on the emission surface side of the saturable absorber 4 does not occur, and the Q-switched laser oscillation does not occur.

Thereafter, when the power of the excitation light of the first wavelength λ1 is accumulated in the solid-state laser medium 3, and the solid-state laser medium 3 comes into a sufficiently excited state, the output of the spontaneous emission light increase. When this exceeds a certain threshold, a light absorption rate in the saturable absorber 4 rapidly decreases, enabling the spontaneous emission light generated in the solid-state laser medium 3 to be transmitted through the saturable absorber 4. Therefore, the light of the first wavelength λ1 by the first resonator 11 is emitted from the solid-state laser medium 3, and the second resonator 12 causes the light of the second wavelength λ2 to resonate between the second reflection layer R2 and the fourth reflection layer R4. Therefore, the Q-switched laser oscillation occurs, and the Q-switched laser pulse is emitted toward a space (space on the right side in FIG. 8) via the fourth reflection layer R4.

A non-linear optical crystal for wavelength conversion can be disposed inside the second resonator 12. The wavelength of the laser pulse after the wavelength conversion can be changed depending on the type of the non-linear optical crystal. Examples of wavelength converting materials include non-linear optical crystals such as LiNbO₃, BBO, LBO, CLBO, BiBO, KTP, and SLT. Furthermore, a phase-matching material similar to them may be used as the wavelength converting material. However, the type of the wavelength converting material is not limited. The second wavelength λ2 can be converted to another wavelength by the wavelength converting material.

The light emitting section 111 according to the present example may be provided with a heat discharging section for preventing a decrease in the oscillation efficiency of the laser light and a decrease in the conversion efficiency of the light wavelength due to thermal interference between the excitation light source and the solid-state laser medium.

The Q-switching operation is a method of obtaining a pulse laser by inserting an opening/closing shutter that prevents oscillation into a laser resonator and switching a Q-value that is a figure of merit of the resonator in a short time when sufficient energy is accumulated in a laser crystal. A method of electrically or mechanically controlling the shutter is referred to as active Q-switching, and a method of automatically opening the shutter by the saturable absorber 4 is referred to as passive Q-switching. By periodically increasing the resonator losses using the saturable absorber 4 inside the resonator, the laser output is turned off. Therefore, the Q-switching is loss switching. Since constant power is constantly transmitted by the excitation, energy is stored in the atoms in the form of an atomic number density difference that is accumulated during a high loss time. When the loss is reduced during the on-time, the large accumulated atomic number density difference is released. Therefore, the light emitting section 111 according to the present example can instantaneously emit a strong short pulse (light beam).

Further, in a non-laser operating state, the Q-switched laser resonator is constituted by a flat mirror, so that a higher order mode is generates, but during laser operation, a thermal lens forms in the material, and the laser resonator transiently changes to a plano-concave or concave-concave shape. As a result, oscillation in the Gaussian horizontal mode becomes possible, that is, a beam having excellent beam quality can be generated, and a light beam having a small divergence angle (a divergence angle of 2 degrees or less) can be emitted from the light emitting section 111.

### Second Configuration Example

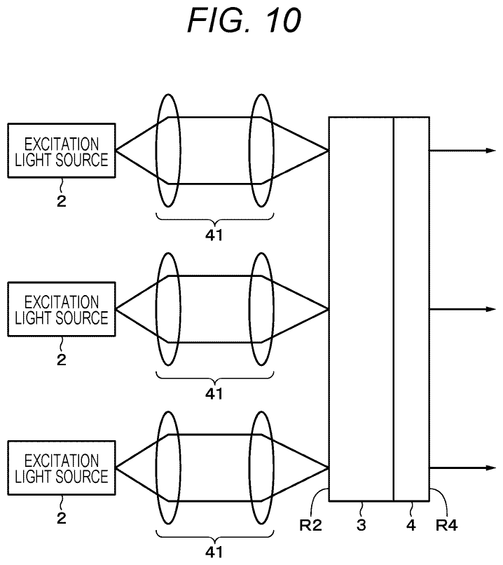

Next, a second configuration example of the light emitting section 111 will be described. FIG. 9 is a diagram illustrating a configuration example of the light emitting section 111 according to the present example. In the present example, the solid-state laser medium 3 and the saturable absorber 4 are joined. As the excitation light source 2, for example, a surface emitting laser array is used. As described above, the second reflection layer R2 is a high reflection layer, and the fourth reflection layer R4 is a partial reflection layer. The excitation light source 2 is not joined to the solid-state laser medium 3 and the saturable absorber 4, and a microlens array 41, which is an example of a condenser lens section, is arranged between the excitation light source 2 and the solid-state laser medium 3. In the light emitting section 111 according to the present example, the light beam emitted from the excitation light source 2 is condensed on the solid-state laser medium 3 by the microlens array 41. Other operations are the same as those in the first configuration example. The light emitting section 111 according to the present example can also emit a light beam having a small divergence angle. The excitation light source 2 may be a light source arranged one-dimensionally or two-dimensionally perpendicular to the traveling direction of the first wavelength λ1 or the second wavelength λ2.

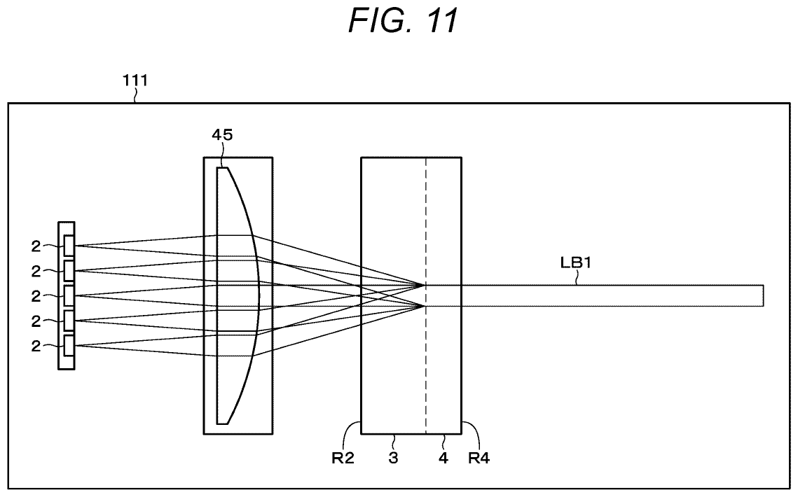

FIG. 10 is a diagram illustrating a concept of an array-shaped light source in which a plurality of light emitting sections 111 and a plurality of microlenses 41 illustrated in FIG. 9 are arranged. The excitation light source 2 may be one in which light sources are arranged, or may be one in which a plurality of light emitting sections is arranged in one light emitting light source. In addition, the microlens may also be one in which the respective lenses are arranged, or may be one component as a microlens array.

### Third Configuration Example

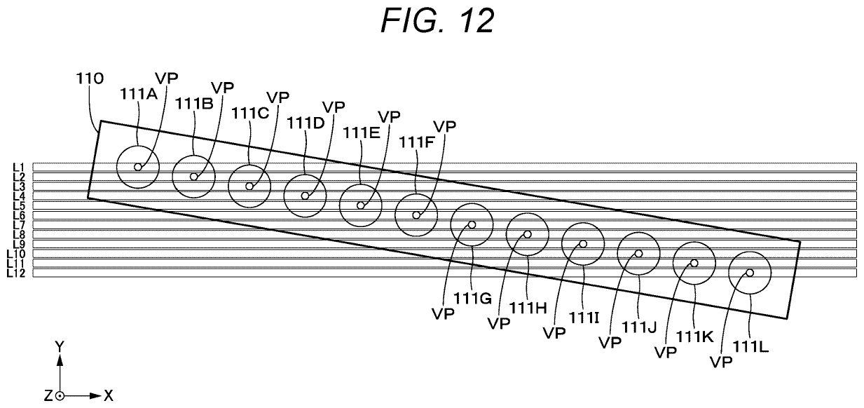

Next, a third configuration example of the light emitting section 111 will be described. FIG. 11 is a diagram illustrating a configuration example of the light emitting section 111 according to the present example. The excitation light source 2 uses a surface emission type laser array, and a plurality of excitation light sources 2 is arranged. The light beams emitted from the plurality of excitation light sources 2 are condensed by one optical lens 45. The condensed light beam enters a predetermined region of the solid-state laser medium 3. Other operations are the same as those in the first configuration example and the second configuration example. Note that, although not illustrated, similarly to FIG. 10, the optical lens 45 may be a microlens array in which a plurality of lenses is arranged. As a result, the light beam is condensed in a plurality of regions of the solid-state laser medium 3, and a light beam having a small divergence angle oscillated by Q-switching in a plurality of arranged regions in the solid-state laser medium 3 is generated. The generated light beam is emitted as a light beam LB1 from the light emitting section 111.

The plurality of configuration examples of the light emitting section 111 has been described above. Note that, in the above description, an example in which a Q-switched laser is used as the light emitting section 111 included in the light emitting element 110 has been described. However, in principle, it is sufficient that a light beam having a narrow divergence angle is emitted from the light emitting section 111. For example, a surface emission type laser using a photonic crystal that emits a light beam having a narrow divergence angle may be used, or a plurality of end face emission type lasers or fiber lasers may be arranged.

[about Generation of Linear Light Beam]

The light beam LB2 which is the parallel light beam emitted from the illumination device 100 described above may be emitted to the irradiation target 1000 as a linear light beam. In an end face emission type laser or a surface emission type laser used in a general distance measuring system, the light intensity of a light beam from one light emitting section can obtain only a light output of about several 10 W (several 100 W at the highest), but the light emitting section 111 (for example, the light emitting section 111 having the above-described first configuration example) according to the present embodiment can obtain a light output of about several 10 KW (several 1000 kW in some cases). Therefore, even if the light beam is expanded in a line shape using a diffusion plate, a cylindrical lens, or the like, a predetermined light intensity can be secured, and a wide distance measurement range can be obtained. In the present embodiment, by condensing light smaller at the virtual light emission point VP, a higher light density can be obtained, and a wider distance measurement range can be obtained.

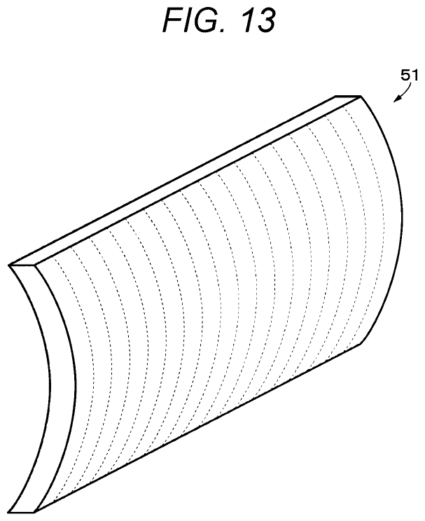

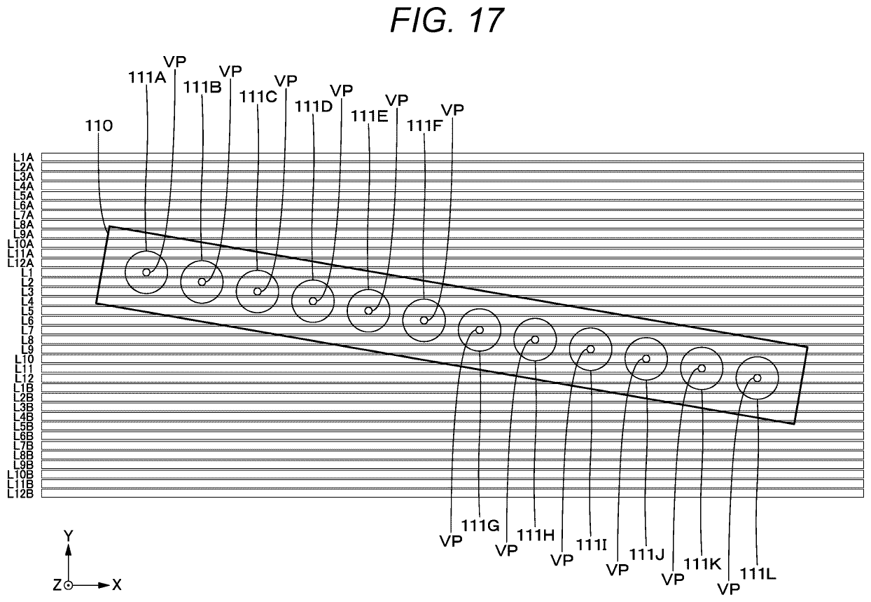

On the other hand, since the interval between the light emitting sections 111 is equal to or more than a certain value with respect to the condensed beam diameter at the virtual light emission point VP, a gap is formed between the linear light beams. In the present embodiment, as illustrated in FIG. 12, the light emitting elements 110 are arranged obliquely, that is, the respective light emitting sections 111 are arranged obliquely to minimize the gap between the linear light beams. Strictly speaking, there is a possibility that displacement in the horizontal direction occurs. However, since in the horizontal direction, the light beam satisfies a field of view (FOV) of about 120 degrees, for example, this positional deviation in the horizontal direction does not cause a problem. Note that, in FIG. 12, a rectangular frame in an oblique direction indicates the light emitting element 110, a large circle in the rectangular frame indicates the light emitting section, and a small circle indicates the virtual light emission point VP formed by condensing the light beam emitted from each light emitting section 111. In addition, a slightly thin rectangle indicates a linear light beam. Similar content of illustration applies to FIGS. 17, 19, 22, 23, 24, 25, and 26.

In the present example, the number of light emitting sections 111 is 12 (light emitting sections 111A, 111B . . . 111L). For example, control is performed to cause the light emitting sections 111 to sequentially emit light from the upper left light emitting section 111A toward the lower right light emitting section 111L.

In addition, L1 in FIG. 12 is a linear light beam obtained by linearly expanding the light beam emitted from the light emitting section 111 located at the uppermost left. L2 in FIG. 12 is a linear light beam obtained by linearly expanding the light beam emitted from the light emitting section 111 located second from the upper left. L3 in FIG. 12 is a linear light beam obtained by linearly expanding the light beam emitted from the light emitting section 111 located third from the upper left. L4 in FIG. 12 is a linear light beam obtained by linearly expanding the light beam emitted from the light emitting section 111 located fourth from the upper left. L5 in FIG. 12 is a linear light beam obtained by linearly expanding the light beam emitted from the light emitting section 111 located fifth from the upper left. L6 in FIG. 12 is a linear light beam obtained by linearly expanding the light beam emitted from the light emitting section 111 located sixth from the upper left. L7 in FIG. 12 is a linear light beam obtained by linearly expanding the light beam emitted from the light emitting section 111 located seventh from the upper left. L8 in FIG. 12 is a linear light beam obtained by linearly expanding the light beam emitted from the light emitting section 111 located eighth from the upper left. L9 in FIG. 12 is a linear light beam obtained by linearly expanding the light beam emitted from the light emitting section 111 located ninth from the upper left. L10 in FIG. 12 is a linear light beam obtained by linearly expanding the light beam emitted from the light emitting section 111 located 10th from the upper left. L11 in FIG. 12 is a linear light beam obtained by linearly expanding the light beam emitted from the light emitting section 111 located 11th from the upper left. L12 in FIG. 12 is a linear light beam obtained by linearly expanding the light beam emitted from the light emitting section 111 located 12th from the upper left.

Note that, in the present example, a configuration in which the light beam is spread in a line shape in the horizontal direction and the light emission of each light emitting section is sequentially switched so that the linear light beam is scanned in the vertical direction has been described. However, a configuration in which the light beam is spread in a line shape in the vertical direction and the light beam is scanned in the horizontal direction may be adopted, or a configuration in which the light beam is spread in an oblique direction may be adopted as necessary.

### Method for Generating Linear Light Beam

### First Example

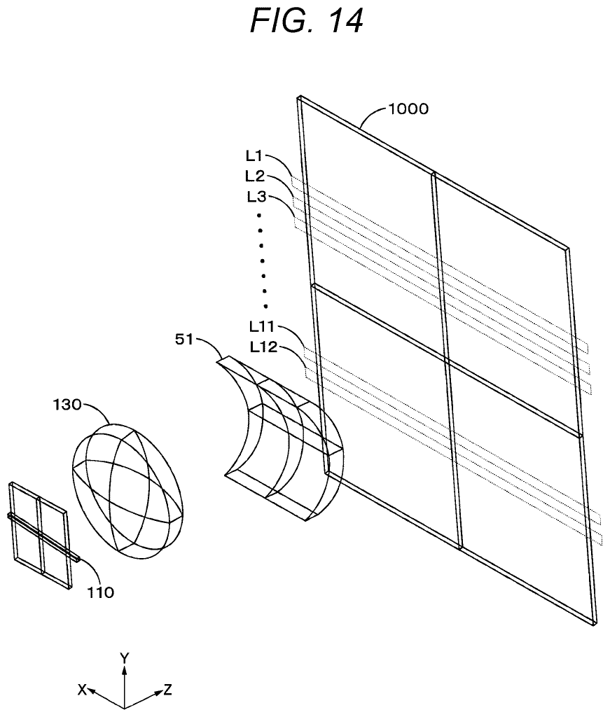

Next, an example of a method for generating the above-described linear light beam will be described. First, a first example of a method for generating a linear light beam will be described. The first example is an example of generating a linear light beam using a diffusion plate. FIG. 13 is a diagram illustrating a diffusion plate (diffusion plate 51) in the present example. The diffusion plate 51 is curved in the vertical direction, and has a linear shape in a direction orthogonal to the vertical direction. With such a shape, a linear light beam can be generated without distortion. Note that the center of curvature R of the diffusion plate 51 is desirably a telecentric position of the optical lens 130. In addition, the curved diffusion plate is an example, and the invention is not limited thereto. It is also possible to use a curved linear light beam using a planar diffusion plate, or to generate a linear light beam that matches the curvature aberration on the detector side.

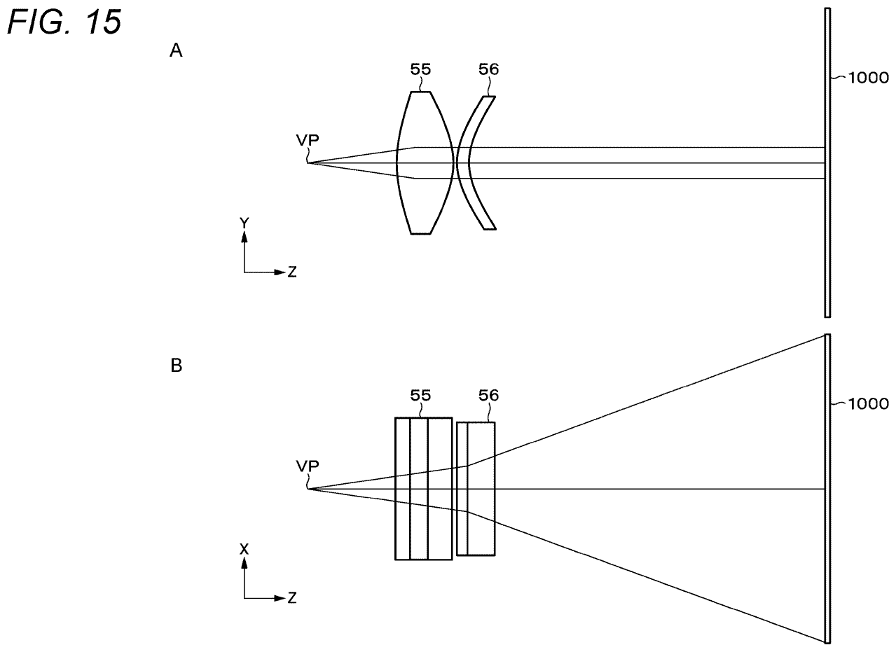

As illustrated in FIG. 14, the diffusion plate 51 is disposed beyond the optical lens 130, that is, between the optical lens 130 and the irradiation target 1000. As a result, the irradiation target 1000 is irradiated with the linear light beam (for example, the linear light beams L1 to L12). Note that a lens or a diffraction grating diffractive optical element (DOE) may be used instead of the diffusion plate 51 in the present example.

### Second Example

Next, a second example of a method for generating a linear light beam will be described. The present example is an example in which a cylindrical lens (cylindrical lens 55) is disposed instead of the optical lens 130, and a diffusion plate (diffusion plate 56) is further disposed beyond the cylindrical lens 55 (between the cylindrical lens 55 and the irradiation target 1000) to generate a linear light beam.

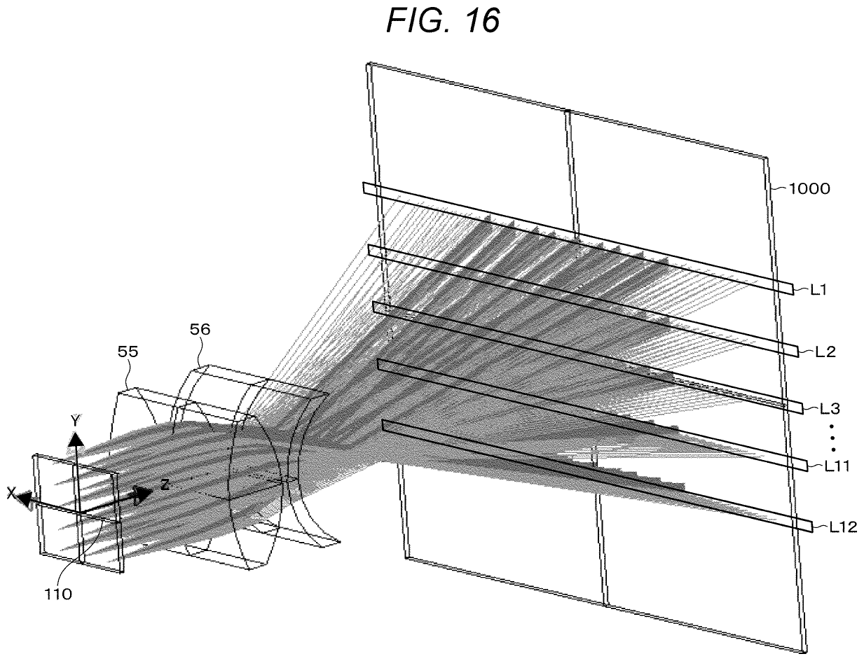

As illustrated in FIG. 15A, the light beam from the virtual light emission point VP becomes substantially parallel light by the cylindrical lens 55 in the Y direction. Meanwhile, the diffusion plate 56 does not act in the Y direction (vertical direction). On the other hand, as illustrated in FIG. 15B, the cylindrical lens 55 does not act in the X direction. Meanwhile, in the X direction (horizontal direction), a linear light beam is diffused by the diffusion plate 56. The diffusion plate 56 enables the generation of a linear light beam and provides the required FOV. Then, as illustrated in FIG. 16, the irradiation target 1000 is irradiated with the linear light beam (for example, the linear light beams L1 to L12) emitted from the diffusion plate 56. Note that FIGS. 14 and 16 are different from each other in the bending direction of the diffusion plate, but FIG. 14 illustrates an example in which the diffusion plate 51 is disposed beyond the telecentric position of the optical lens 130, and FIG. 16 illustrates an example in which the diffusion plate 56 is disposed in front of the telecentric position of the cylindrical lens 55, and an example in which the center of the curvature R is the telecentric position is illustrated in another case. The optical element for generating the linear light beam described above may be included.

### Application Example Using Linear Light Beam

### First Application Example

Next, an application example using the linear light beam generated by the above-described method will be described. A first application example is an example in which the FOV is expanded by generating a duplicated pattern in the Y direction of the linear light beam generated by the above-described method using the diffraction grating (diffraction grating 58). For example, as illustrated in FIG. 17, 12 linear light beams (linear light beams L1A, L1A, . . . L12A) are obtained by replicating the linear light beams L1 to L12 in the upward direction of the linear light beams L1 to L12 based on the light beams emitted from the 12 light emitting sections 111A to 111L. Further, the linear light beams L1 to L12 are duplicated in the downward direction of the linear light beams L1 to L12 based on the light beams emitted from the 12 light emitting sections 111, so that 12 linear light beams (linear light beams L1B, L1B . . . L12B) are obtained.

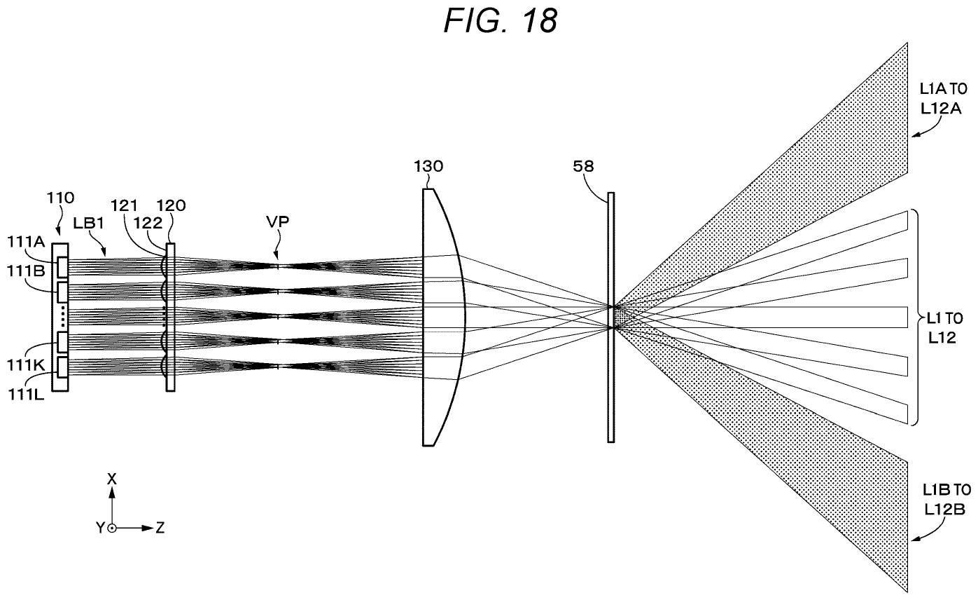

As illustrated in FIG. 18, the diffraction grating 58 is disposed between the optical lens 130 and the irradiation target 1000. Note that, also in order to replicate the linear light beam without distortion in the vertical direction, the distance between the optical lens 130 and the diffraction grating 58 is desirably substantially equal to the telecentric position of the optical lens 130 (focal length of the optical lens 130). The diffraction grating 58 replicates the linear light beam, which may enlarge the FOV. Note that, from the viewpoint of enlarging the FOV, it is preferable that the linear light beam is duplicated in the up-down direction, but the linear light beam may be duplicated in either direction.

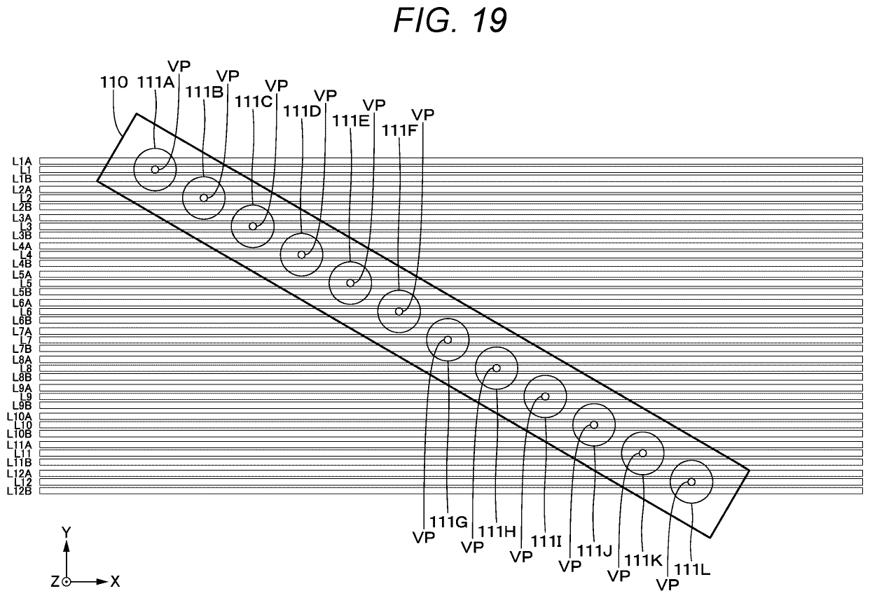

As illustrated in FIG. 19, the linear light beam may be duplicated by the diffraction grating 58 so as to be vertically adjacent to a predetermined linear light beam. For example, the linear light beam LA and the linear light beam L1B are duplicated by the diffraction grating 58 so as to be vertically adjacent to the linear light beam L1, and the linear light beam L2A and the linear light beam L2B are duplicated by the diffraction grating 58 so as to be vertically adjacent to the linear light beam L2. Similarly, the linear light beam is replicated by the diffraction grating 58 so as to be vertically adjacent to the other linear light beams. The duplicated linear light beams may interpolate between the original linear light beams. The diffraction grating 58 described above may be included.

### Second Application Example

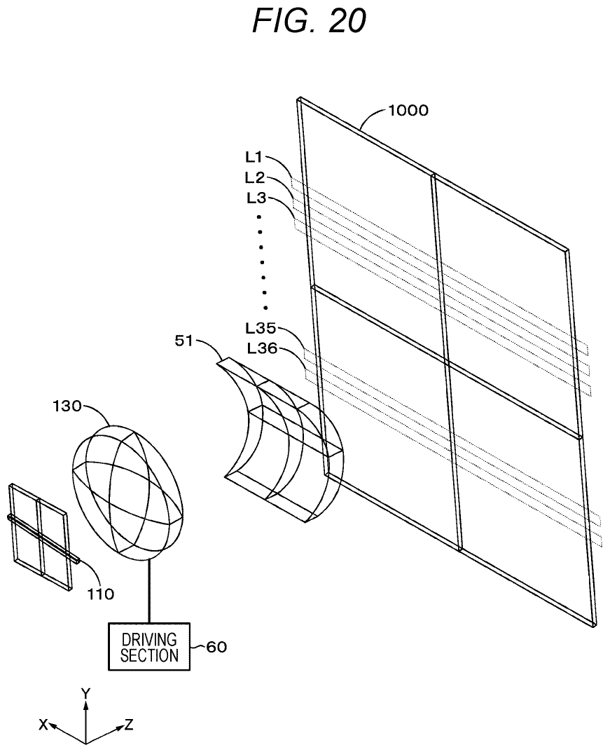

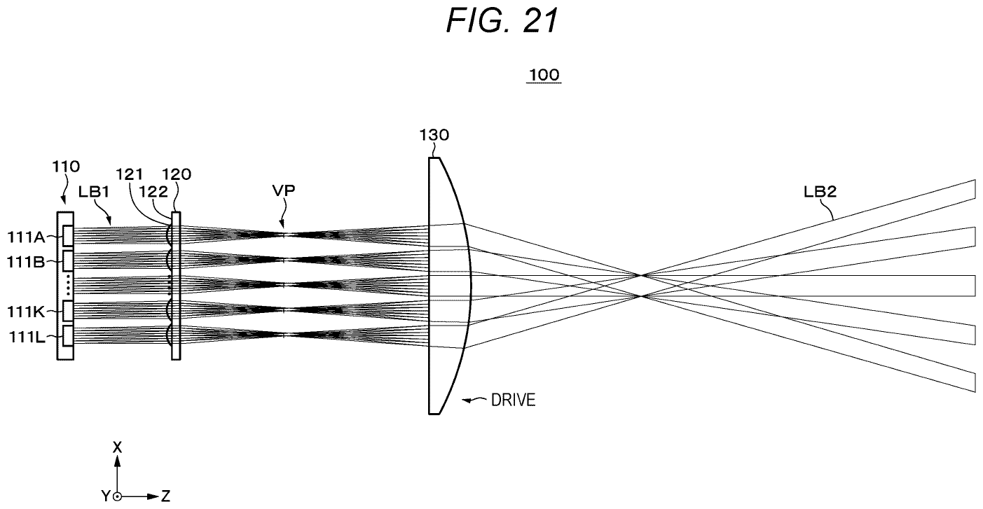

The present application example is an example in which the number of linear light beams emitted to the irradiation target 1000 is increased by driving the optical lens 130 by a driving section. As illustrated in FIG. 20, for example, the driving section 60 is connected to the optical lens 130. As schematically illustrated in FIG. 21, the optical lens 130 is driven in the Y direction by the driving section 60. As the driving section 60, a voice coil motor (VCM), a piezoelectric element, a shape memory alloy element, a liquid crystal element, or the like can be used.

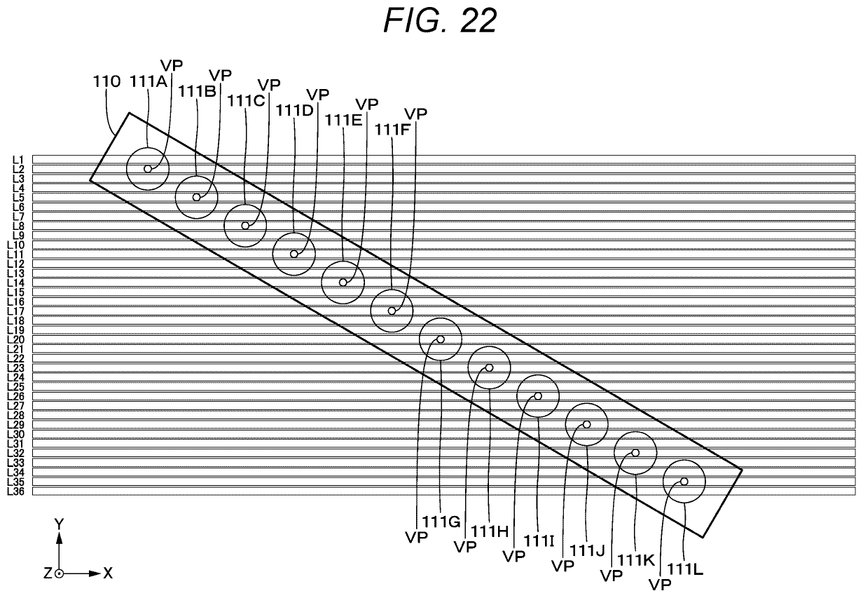

When the optical lens 130 is driven by the driving section 60, the linear light beam can be scanned in the driving direction (in the present example, the Y direction). Since the linear light beam can be scanned, as illustrated in FIG. 22, the number of linear light beams (the linear light beams L1 to L36 in the illustrated example) with which the irradiation target 1000 is irradiated can be increased, and the resolution can be improved. In addition, as compared with the case of using the diffraction grating, the resolution can be improved without narrowing the distance measurement range, and the number of components can be reduced. Note that the driving section 60 may be connected to the light emitting element 110 instead of the optical lens 130, and the light emitting element 110 may be driven by the driving section 60. Furthermore, the light emitting element 110 and the optical lens 130 may be driven by the driving section 60. The present application example is also applicable to a configuration in which a linear light beam is not duplicated. Note that the driving section 60 may be included in the illumination device 100 or may be driven by another device.

### Another Example of Light Emitting Element

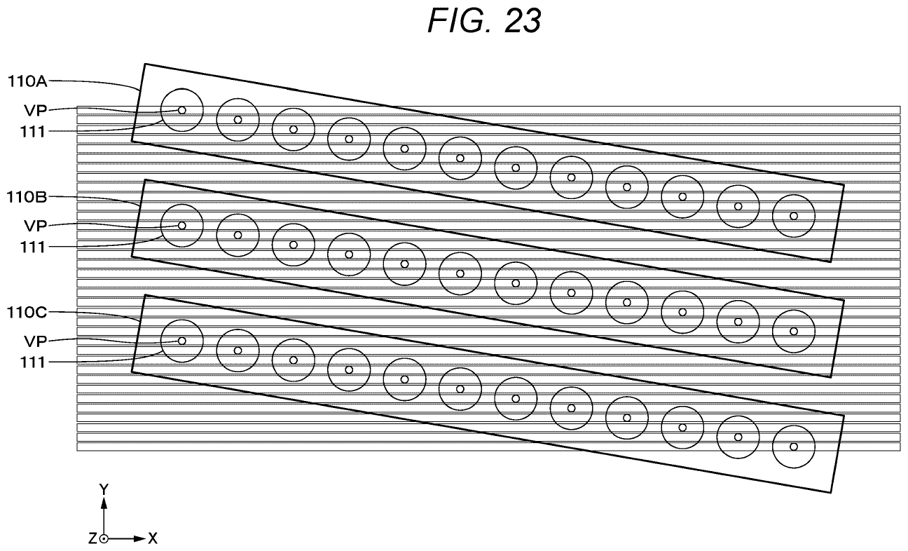

Next, another example of the light emitting element 110 will be described. The light emitting sections 111 included in the light emitting element 110 are not limited to be arranged in a line, and may be arranged two-dimensionally. In addition, the number of light emitting elements 110 included in the illumination device 100 may be a plurality instead of one. For example, as illustrated in FIG. 23, the illumination device 100 may include three light emitting elements 110 (light emitting element 110A, 110B, and 110C). Since desired resolution and FOV can be changed only by changing the number of the light emitting elements 110, it is possible to support many system specifications, and the illumination device 100 can be a general-purpose device.

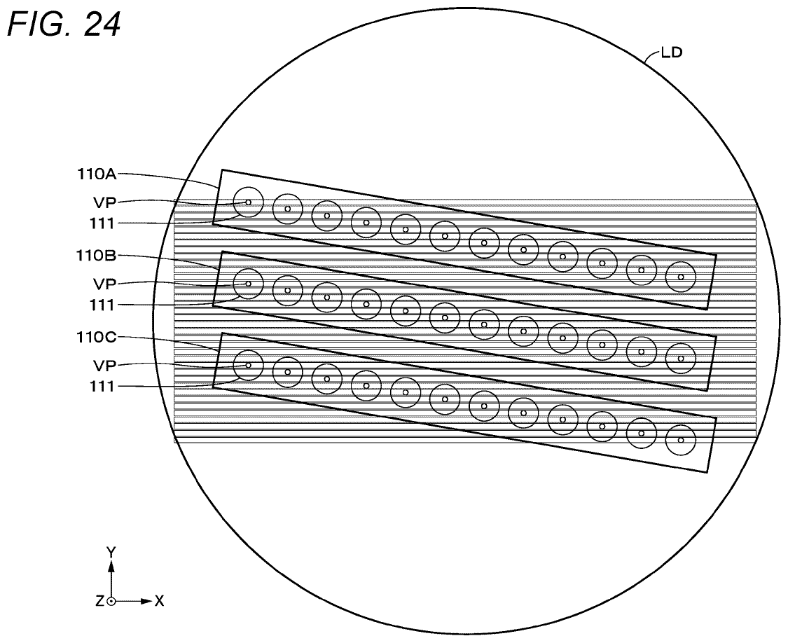

Furthermore, in a case where the illumination device 100 has a configuration including the plurality of light emitting elements 110, it is preferable that the light emitting elements 110 are not arranged in a line, but are arranged to be adjacent to each other in the Y direction, for example, as illustrated in FIG. 23. For example, it is preferable that the light emitting elements 110 are arranged obliquely such that the light emitting section 111 forms a predetermined angle with respect to the longitudinal direction of the virtually projected linear light beam, and the light emitting elements 110 are arranged along the Y direction. As a result, as illustrated in FIG. 24, as compared with an aspect in which the light emitting elements 110 are arranged in a line, the optical lens diameter LD of the optical lens 130 can be effectively used, and the illumination device 100 can be downsized. In addition, in a case where the light emitting elements 110 are two-dimensionally arranged, it is most preferable from the viewpoint of efficient arrangement that the length in the horizontal direction of the arranged region is substantially equal to the length of the vertical region.

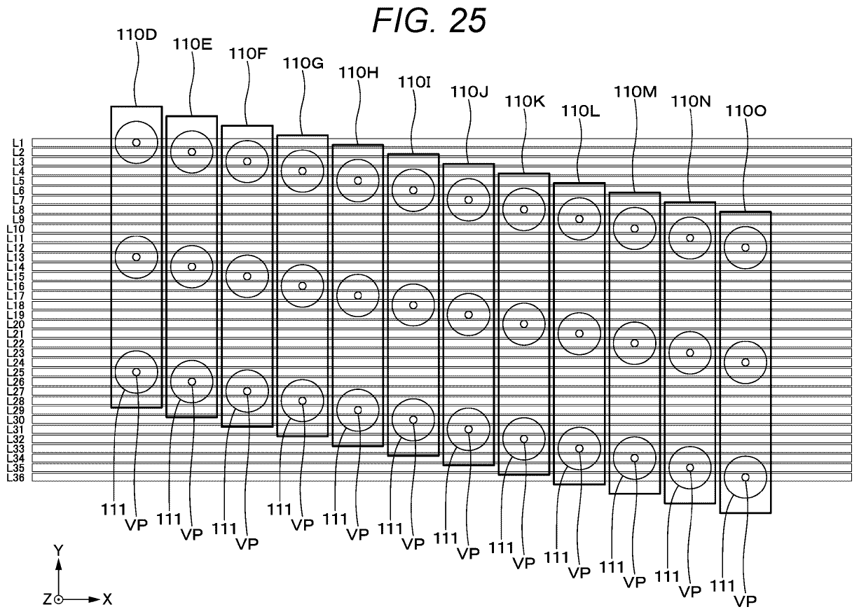

FIG. 25 is a diagram for explaining another example of the light emitting element. The illumination device 100 includes, for example, 12 light emitting elements (light emitting elements 110D, 110E, 110F . . . 110O). Each light emitting element according to the present example includes, for example, three light emitting sections 111. The light emitting elements 110 are arranged such that the three light emitting sections 111 are arranged in a direction (Y direction) substantially orthogonal to the line direction (X direction) of the linear light beam, and are arranged adjacent to each other.

The light emitting sections 111 of the light emitting elements 110 are controlled to simultaneously emit light. According to such control, for example, first, the three light emitting sections 111 included in the light emitting element 110D simultaneously emit light, and at the next light emission timing, the three light emitting sections 111 included in the light emitting element 110E adjacent to the light emitting element 110D simultaneously emit light. Then, at the next light emission timing, the three light emitting sections 111 included in the light emitting element 110F adjacent to the light emitting element 110E simultaneously emit light. In this manner, the light emitting elements as the light emission target are sequentially switched, and at the end of a certain light emission cycle (one frame), the three light emitting sections 111 included in the light emitting element 110O emit light.

When the three light emitting sections 111 included in the light emitting element 110D simultaneously emit light, the irradiation target 1000 is irradiated with the linear light beams L1, L13, and L25. In addition, when the three light emitting sections 111 included in the light emitting element 110E simultaneously emit light, the irradiation target 1000 is irradiated with the linear light beams L2, L14, and L26. When the three light emitting sections 111 included in the light emitting element 110F simultaneously emit light, the irradiation target 1000 is irradiated with the linear light beams L3, L15, and L27.

When the three light emitting sections 111 included in the light emitting element 110G simultaneously emit light, the irradiation target 1000 is irradiated with the linear light beams L4, L16, and L28. When the three light emitting sections 111 included in the light emitting element 110H simultaneously emit light, the irradiation target 1000 is irradiated with the linear light beams L5, L17, and L29. When the three light emitting sections 111 included in the light emitting element 110I simultaneously emit light, the irradiation target 1000 is irradiated with the linear light beams L6, L18, and L30. When the three light emitting sections 111 included in the light emitting element 110J simultaneously emit light, the irradiation target 1000 is irradiated with the linear light beams L7, L19, and L31.

When the three light emitting sections 111 included in the light emitting element 110K simultaneously emit light, the irradiation target 1000 is irradiated with the linear light beams L8, L20, and L32. When the three light emitting sections 111 included in the light emitting element 110L simultaneously emit light, the irradiation target 1000 is irradiated with the linear light beams L9, L21, and L33. When the three light emitting sections 111 included in the light emitting element 110M simultaneously emit light, the irradiation target 1000 is irradiated with the linear light beams L10, L22, and L34. When the three light emitting sections 111 included in the light emitting element 110N simultaneously emit light, the irradiation target 1000 is irradiated with the linear light beams L11, L23, and L35. When the three light emitting sections 111 included in the light emitting element 110O simultaneously emit light, the irradiation target 1000 is irradiated with the linear light beams L12, L24, and L36. As a result, linear light beams based on light beams emitted from light emitting sections included in a certain light emitting element (first light emitting element) are interpolated by linear light beams based on light beams emitted from light emitting sections included in another light emitting element (second light emitting element) adjacent to the light emitting element.

According to the arrangement mode illustrated in FIG. 25, it is possible to increase the interval between the light emitting sections 111 included in one light emitting element 110 without increasing the size of the light emitting element 110 and reducing the number of linear light beams. As a result, even if the light emitting sections 111 (three light emitting sections in the present example) included in one light emitting element 110 simultaneously emit light, the number of light beams entering the pupil is limited (for example, limited to one light beam), so that the safety of the illumination device 100 can be improved. While the safety of the illumination device 100 is improved, a higher light output can be performed by the light emitting section 111, and a wide distance measurement range can be obtained.

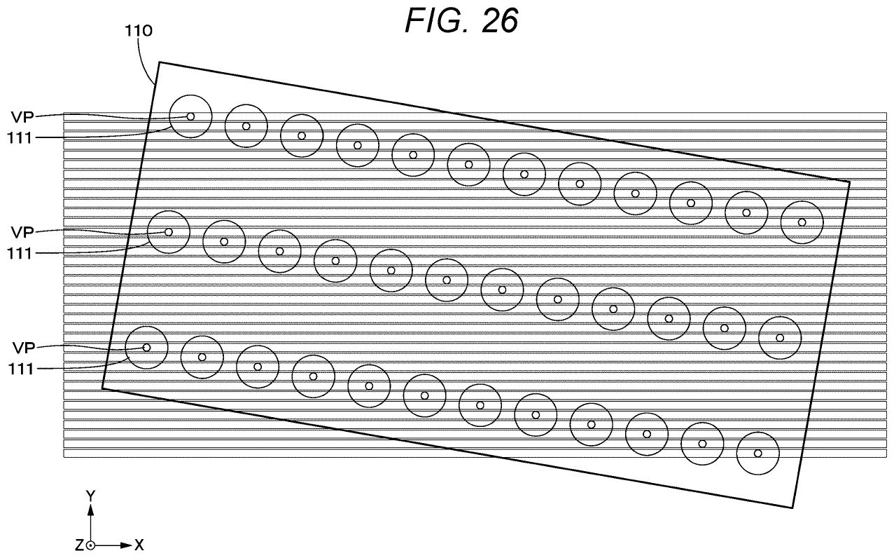

As illustrated in FIG. 26, one light emitting element 110 may include a plurality of light emitting sections 111 arranged two-dimensionally. By integrating the light emitting sections 111 into one light emitting element 110, it is easy to assemble the illumination device 100. In this case, all of the light emitting sections 111 may emit light, or the plurality of light emitting sections 111 may be switched in a predetermined order (scanning direction) to emit light. Furthermore, a wiring in the light emitting element 110 may be added, and switching of light emission of the plurality of light emitting sections 111 may be performed in a manner similar to the example described with reference to FIG. 25.

### [Method for Driving Illumination Device]

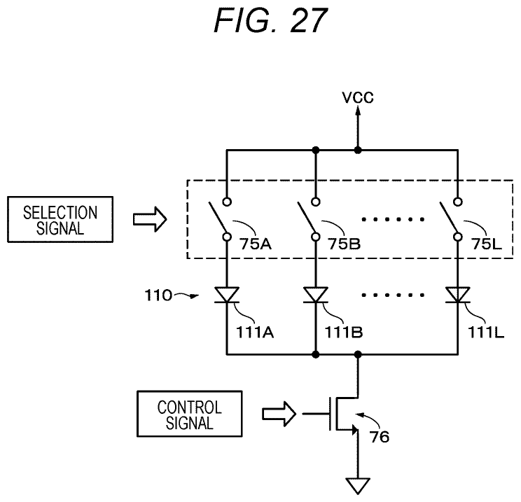

Next, an example of a method for driving the illumination device 100 according to one embodiment will be described. FIG. 27 illustrates a configuration example of a drive circuit of the illumination device 100. As illustrated in the drawing, the light emitting element 110 includes a plurality of light emitting sections 111. In the present example, the number of light emitting sections 111 will be described as 12 (light emitting sections 111A, 111B . . . 111L, see FIG. 12).

The anode of the light emitting section 111A is connected to the power supply VCC via a switch 75A. The anode of the light emitting section 111B is connected to the power supply VCC via a switch 75B. The anode of the light emitting section 111C is connected to the power supply VCC via a switch 75C. Similarly, anodes of the other light emitting sections 111 are also connected to the power supply VCC via a switch.

The cathodes of the light emitting sections 111A to 111L are common, and the respective cathodes are connected to a switching element 76. As the switching element 76, for example, an n-type metal oxide semiconductor field effect transistor (MOSFET) can be applied. The switching element 76 may be a p-type MOSFET or a bipolar transistor.

A selection signal is supplied to the switches 75A to 75L. According to the selection signal, only the switch corresponding to the light emitting section 111 as the light emission target is turned on, and the other switches are turned off. In addition, a control signal is supplied to the switching element 76. For example, at the light emission timing, the switching element 76 is turned on by the supply of the control signal, whereby a current flows through the light emitting section 111 in which the switch is turned on, in other words, the light emitting section 111 whose anode is connected to the power supply VCC, and the light emitting section 111 as the light emission target emits light. Generation of the selection signal and the control signal and switching control based on these signals are performed by the control section 200, for example. The illumination device 100 may include a control section, and the control section may perform the above-described switching control and the like.

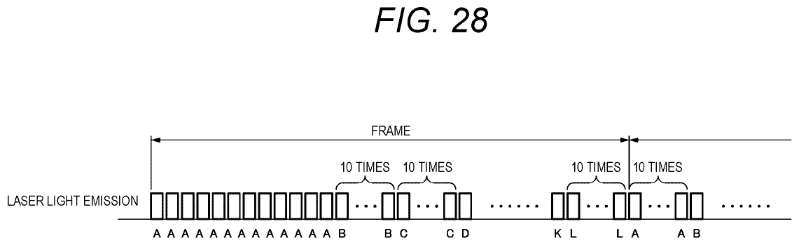

FIG. 28 illustrates an example of a light emission sequence of the illumination device 100. For example, a section in which one distance measurement image is generated in the distance measuring device 1 is referred to as a “frame”, and one frame is set to a time such as 33.3 msec (frequency 30 Hz). As the distance measuring pulse, for example, a light pulse of several 100 psec is emitted at a cycle of 100 μsec. A plurality of accumulation sections with different conditions can be provided in the frame.

The example illustrated in FIG. 28 is an example in which after one light emitting section is caused to emit light a plurality of times (after the irradiation target 1000 is irradiated with one linear light beam a plurality of times), the next light emitting section is caused to emit light a plurality of times (the irradiation target 1000 is irradiated with the next linear light beam a plurality of times). For example, after the light emitting section 111A emits light 10 times and irradiates the irradiation target 1000 with the linear light beam L1 10 times, the light emitting section 111B emits light 10 times and irradiates the irradiation target 1000 with the linear light beam L2 10 times. All the light emitting sections (light emitting sections 111A to 111L) emit light, and the irradiation target 1000 is irradiated with the linear light beams L1 to L12, whereby one frame is formed. Of course, the number of times of light emission is not limited to 10 and may be other numbers. In the light emission sequence according to the present example, histogram processing on the side of the light receiving section 210 and the distance measuring section 220 is facilitated.

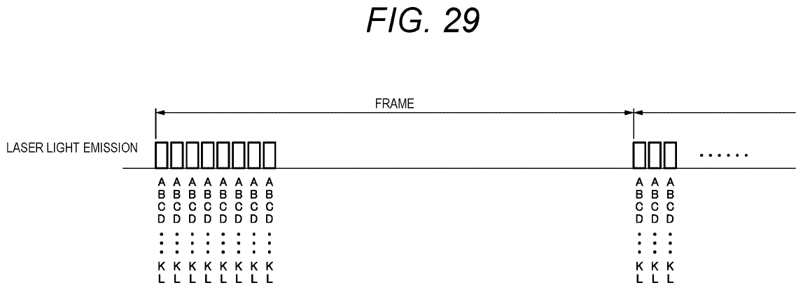

FIG. 29 illustrates another example of the light emission sequence of the illumination device 100. The example illustrated in FIG. 29 is an example in which the light emitting sections 111A to 111L are caused to emit light once, and then the light emitting sections are repeated a plurality of times to form one frame. In FIG. 29, the number of repetitions is 8, but the number of repetitions is not limited thereto. In the light emission sequence according to the present example, since the light emission portion is switched, safety based on the viewpoint of eye safe can be improved.

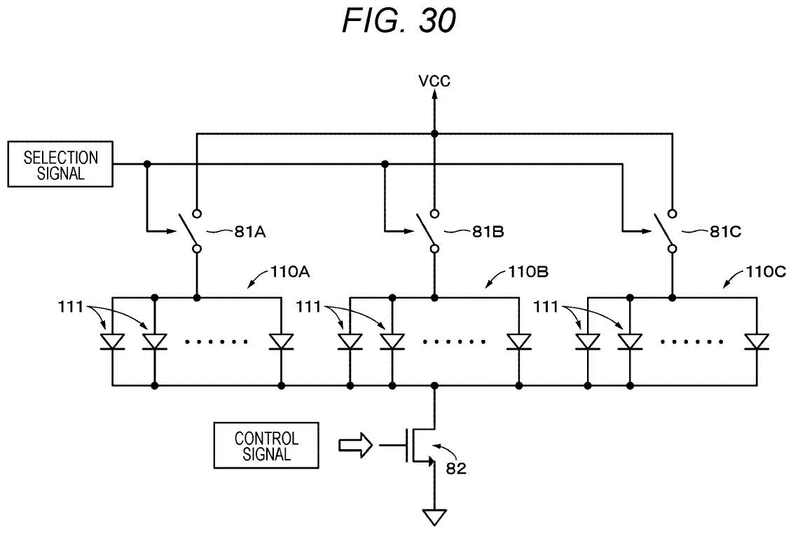

FIG. 30 illustrates another configuration example of the drive circuit of the illumination device 100. The drive circuit illustrated in FIG. 30 is a drive circuit corresponding to a configuration in which the illumination device 100 includes a plurality of light emitting elements 110 (for example, three light emitting elements, see FIG. 24). The anode side of the light emitting section 111 included in the light emitting element 110A is common, and is connected to the power supply VCC via a switch 81A. In addition, the anode of the light emitting section 111 included in the light emitting element 110B is common, and is connected to the power supply VCC via a switch 81B. In addition, the anode side of the light emitting section 111 included in the light emitting element 110C is common, and is connected to the power supply VCC via a switch 81C. A cathode of the light emitting section 111 included in each light emitting element is common, and connected to a switching element 82.

A selection signal is supplied to the switches 81A, 81B, and 81C. According to the selection signal, only the switch corresponding to the light emitting element 110 as the light emission target is turned on, and the other switches are turned off. In addition, a control signal is supplied to the switching element 82. For example, at the light emission timing, the switching element 82 is turned on by the supply of the control signal, and thus, a current flows through the light emitting section 111 in which the switch is turned on, in other words, the light emitting section 111 included in the light emitting element 110 whose anode is connected to the power supply VCC, and the light emitting element 110 as the light emission target emits light. Generation of the selection signal and the control signal and switching control based on these signals are performed by the control section 200, for example. The illumination device 100 may include a control section, and the control section may perform the above-described switching control and the like.

Note that, in the circuit configuration illustrated in FIG. 30, similarly to in FIG. 27, a switch may be provided between the power supply VCC and each light emitting section 111 to enable individual driving of the light emitting section 111 in the light emitting element 110.

### Effects Obtained by One Embodiment

One embodiment of the present disclosure has been described above. According to one embodiment, for example, the following effects can be obtained.

The light output of the light beam from the light emitting section can be increased, and the divergence angle can be decreased. As a result, the diameter of each of the lens sections arranged beyond the light emitting section can be reduced, and the distance measurement range can be expanded.

In addition, since the divergence angle can be reduced, it is not necessary to increase the interval between the light emitting sections in order to prevent interference between a light beam emitted from a certain light emitting section and a light beam emitted from a light emitting section adjacent to the light emitting section. Therefore, the illumination device can be reduced in size. In addition, the illumination device can be manufactured at low cost.

Note that advantageous effects described in the present specification are merely examples and are not limited, and other advantageous effects may be provided.

### <Modifications>

Although the embodiment of the present disclosure has been specifically described above, the content of the present disclosure is not limited to the above-described embodiment, and various modifications based on the technical idea of the present disclosure are possible.

In addition, the configurations, methods, steps, shapes, materials, numerical values, and the like of the above-described embodiment can be appropriately changed without departing from the gist of the present disclosure. In addition, a plurality of configuration examples described in one embodiment can be combined or replaced with each other.

### Application Examples

Further, the technology according to the present technology can be applied to various products without being limited to the application examples described above. For example, the technology according to the present technology may be realized as a device mounted on any type of mobile body such as an automobile, an electric vehicle, a hybrid electric vehicle, a motorcycle, a bicycle, a personal mobility, an airplane, a drone, a ship, a robot, a construction machine, or an agricultural machine (tractor).

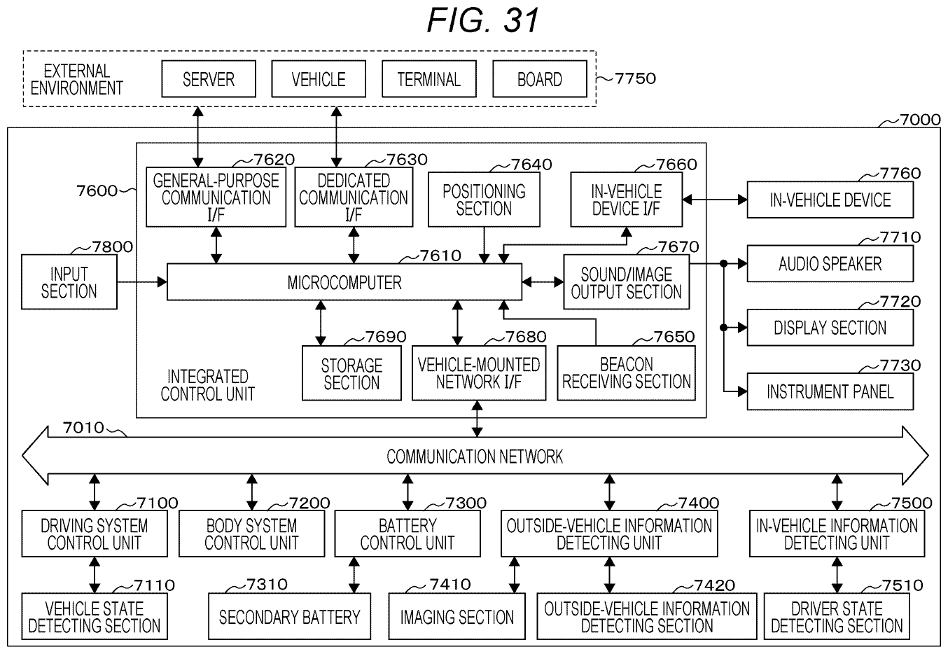

FIG. 31 is a block diagram depicting an example of schematic configuration of a vehicle control system 7000 as an example of a mobile body control system to which the technology according to an embodiment of the present technology can be applied. The vehicle control system 7000 includes a plurality of electronic control units connected to each other via a communication network 7010. In the example depicted in FIG. 31, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 31 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices is integrated.

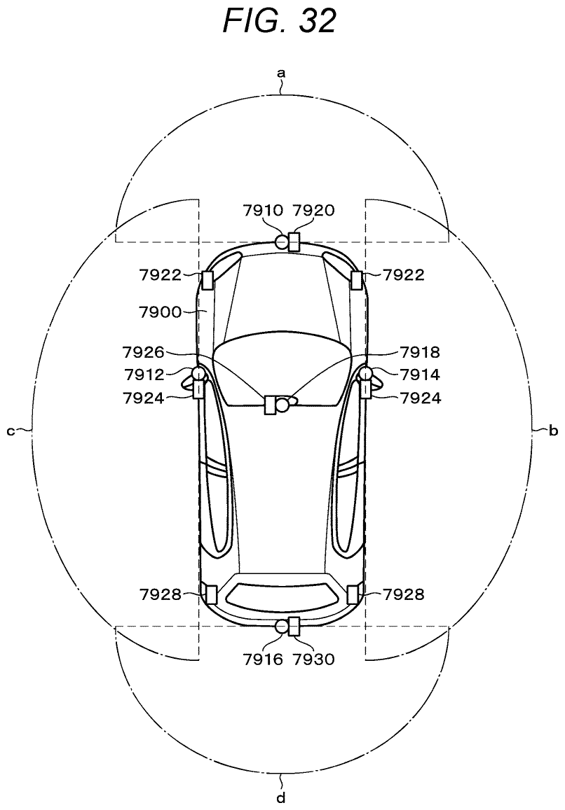

FIG. 32 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 32 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 31, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 31, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 31 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

In the vehicle control system 7000 described above, the illumination device of the present technology can be applied to, for example, an outside-vehicle information detecting section.

Note that the present technology may also have the following configurations.

(1)

An illumination device including:
a plurality of light emitting sections arranged in an array and emitting light beams substantially parallel to each other;
a condensing section that condenses a light beam emitted from each light emitting section; and
a conversion section that makes light beams diverging after light is condensed substantially parallel to each other and changes emission directions of the light beams.
   (2)

The illumination device according to (1),
in which a divergence angle of the light beam emitted from the light emitting section is 2 degrees or less.
   (3)

The illumination device according to (1) or (2),
in which the light emitting section includes an excitation light source layer, a laser medium, and a saturable absorber.
   (4)

The illumination device according to (3),
in which the light emitting section has a structure in which the excitation light source layer, the laser medium, and the saturable absorber are laminated.
   (5)

The illumination device according to (3) or (4),
in which the excitation light source layer includes a first reflection layer with respect to a first wavelength and an active layer that performs surface emission of the first wavelength,
the laser medium is arranged on a rear side of an optical axis of the excitation light source layer, and includes a second reflection layer with respect to a second wavelength on a first surface facing the excitation light source layer and a third reflection layer with respect to the first wavelength on a second surface opposite to the first surface,
the illumination device further including: a fourth reflection layer with respect to the second wavelength disposed on the second surface or disposed on a rear side of the optical axis with respect to the second surface;
a first resonator that causes light having the first wavelength to resonate between the first reflection layer and the third reflection layer; and
a second resonator that causes light having the second wavelength to resonate between the second reflection layer and the fourth reflection layer,
the saturable absorber includes the fourth reflection layer on a third surface opposite to the laser medium, and
an optical axis of the excitation light source layer, an optical axis of the laser medium, and an optical axis of the saturable absorber are arranged on one axis.
   (6)

The illumination device according to (3),
in which the laser medium and the saturable absorber are laminated and disposed,
the illumination device further including a condenser lens section that condenses the light beam emitted from the excitation light source layer on the laser medium.
   (7)

The illumination device according to any one of (1) to (6), further including
an optical element that converts the light beam emitted from the conversion section into a linear light beam.
   (8)

The illumination device according to (7), further including
a diffraction grating that divides the linear light beam into a plurality of beams.
   (9)

The illumination device according to (7) or (8),
in which at least one of the conversion section or the plurality of light emitting sections is driven by a driving section to scan the linear light beam.
   (10)

The illumination device according to (9), further including
the driving section.
   (11) The illumination device according to (10),
in which the driving section includes any one of a VCM, a piezoelectric element, a shape memory alloy element, and a liquid crystal element.
   (12)

The illumination device according to (7), further including:
a first light emitting element including a plurality of light emitting sections arranged in a direction substantially orthogonal to a line direction of the linear light beam; and
a second light emitting element that is adjacent to the first light emitting element and includes a plurality of light emitting sections arranged in a direction substantially perpendicular to the line direction of the linear light beam,
in which the linear light beam based on the light beam emitted from the first light emitting element is interpolated by the linear light beam based on the light beam emitted from the second light emitting element.
   (13)

A distance measuring device including:
the illumination device according to any one of (1) to (12);
a control section that controls the illumination device;
a light receiving section that receives reflected light reflected by a target object; and
a distance measuring section that calculates a distance measurement distance from image data obtained by the light receiving section.
   (14)

An in-vehicle device including the distance measuring device according to (13).

### REFERENCE SIGNS LIST

1 Distance measuring device
2 Excitation light source
3 Solid-state laser medium
4 Saturable absorber
41 Microlens array
51, 56 Diffusion plate
55 Cylindrical lens
60 Driving section
100 Illumination device
110 Light emitting element
111 Light emitting section
120 Microlens array
130 Optical lens
200 Control section
210 Light receiving section
220 Distance measuring section

1. An illumination device comprising:
a plurality of light emitting sections arranged in an array and emitting light beams substantially parallel to each other;
a condensing section that condenses a light beam emitted from each light emitting section; and
a conversion section that makes light beams diverging after light is condensed substantially parallel to each other and changes emission directions of the light beams.

2. The illumination device according to claim 1,
wherein a divergence angle of the light beam emitted from the light emitting section is 2 degrees or less.

3. The illumination device according to claim 1,
wherein the light emitting section includes an excitation light source layer, a laser medium, and a saturable absorber.

4. The illumination device according to claim 3,
wherein the light emitting section has a structure in which the excitation light source layer, the laser medium, and the saturable absorber are laminated.

5. The illumination device according to claim 3,
wherein the excitation light source layer includes a first reflection layer with respect to a first wavelength and an active layer that performs surface emission of the first wavelength,
the laser medium is arranged on a rear side of an optical axis of the excitation light source layer, and includes a second reflection layer with respect to a second wavelength on a first surface facing the excitation light source layer and a third reflection layer with respect to the first wavelength on a second surface opposite to the first surface,
the illumination device further comprising: a fourth reflection layer with respect to the second wavelength disposed on the second surface or disposed on a rear side of the optical axis with respect to the second surface;
a first resonator that causes light having the first wavelength to resonate between the first reflection layer and the third reflection layer; and
a second resonator that causes light having the second wavelength to resonate between the second reflection layer and the fourth reflection layer,
the saturable absorber includes the fourth reflection layer on a third surface opposite to the laser medium, and
an optical axis of the excitation light source layer, an optical axis of the laser medium, and an optical axis of the saturable absorber are arranged on one axis.

6. The illumination device according to claim 3,
wherein the laser medium and the saturable absorber are laminated and disposed,
the illumination device further comprising a condenser lens section that condenses the light beam emitted from the excitation light source layer on the laser medium.

7. The illumination device according to claim 1, further comprising
an optical element that converts the light beam emitted from the conversion section into a linear light beam.

8. The illumination device according to claim 7, further comprising
a diffraction grating that divides the linear light beam into a plurality of beams.

9. The illumination device according to claim 7,
wherein at least one of the conversion section or the plurality of light emitting sections is driven by a driving section to scan the linear light beam.

10. The illumination device according to claim 9, further comprising
the driving section.

11. The illumination device according to claim 10,
wherein the driving section includes any one of a VCM, a piezoelectric element, a shape memory alloy element, and a liquid crystal element.

12. The illumination device according to claim 7, further comprising:
a first light emitting element including a plurality of light emitting sections arranged in a direction substantially orthogonal to a line direction of the linear light beam; and
a second light emitting element that is adjacent to the first light emitting element and includes a plurality of light emitting sections arranged in a direction substantially perpendicular to the line direction of the linear light beam,
wherein the linear light beam based on the light beam emitted from the first light emitting element is interpolated by the linear light beam based on the light beam emitted from the second light emitting element.

13. A distance measuring device comprising:
the illumination device according to claim 1;
a control section that controls the illumination device;
a light receiving section that receives reflected light reflected by a target object; and
a distance measuring section that calculates a distance measurement distance from image data obtained by the light receiving section.

14. An in-vehicle device comprising the distance measuring device according to claim 13.
